(19) United States
(12) Patent Application Publication
(10) Pub. No.: US 2023/0026747 A1
(43) Pub. Date: Jan. 26, 2023

(54) SOLID-STATE IMAGING APPARATUS AND METHOD FOR MANUFACTURING THE SAME

(71) Applicant: SONY SEMICONDUCTOR SOLUTIONS CORPORATION, KANAGAWA (JP)

(72) Inventor: YUSUKE MORIYA, KUMAMOTO (JP)

(21) Appl. No.: 17/784,715

(22) PCT Filed: Oct. 28, 2020
(86) PCT No.: PCT/JP2020/040473

§ 371 Date: Jun. 13, 2022

(30) Foreign Application Priority Data
Dec. 19, 2019 (JP) 2019-229355

(51) Int. Cl. H01L 27/146

(52) U.S. Cl. CPC H01L 27/14627; H01L 27/14645; H01L 27/1462; H01L 27/14621; H01L 27/14623; H01L 27/1463; H01L 27/14685

(57) ABSTRACT

[Object] A solid-state imaging apparatus that can suppress degradation of image quality caused by a groove between lenses is provided, and a method for manufacturing the solid-state imaging apparatus is also provided.

[Solving Means]

A solid-state imaging apparatus according to the present disclosure includes multiple photoelectric conversion sections, and multiple lenses provided above the multiple photoelectric conversion sections. The multiple lenses each include a groove provided between the lenses, and the groove includes a bottom surface shaped to protrude downward.

### TECHNICAL FIELD

The present disclosure relates to a solid-state imaging apparatus and a method for manufacturing the solid-state imaging apparatus.

### BACKGROUND ART

For prevention of color mixture between pixels in a solid-state imaging apparatus, grooves may each be provided between adjacent on-chip lenses. This makes it possible to restrain light incident on an on-chip lens of one pixel from entering an on-chip lens of another pixel, which would otherwise cause color mixture.

### CITATION LIST

### Patent Literature

### [PTL 1}

Japanese Patent Laid-open No. 2008-270679

### SUMMARY

### Technical Problem

However, with the grooves provided between the adjacent on-chip lenses, light may be incident on a light blocking film or the like from the groove, degrading the image quality of the solid-state imaging apparatus.

Thus, the present disclosure provides a solid-state imaging apparatus that can suppress degradation of image quality caused by the groove between the lenses, and also provides a method for manufacturing the solid-state imaging apparatus.

### Solution to Problem

A solid-state imaging apparatus according to a first aspect of the present disclosure includes multiple photoelectric conversion sections and multiple lenses provided above the multiple photoelectric conversion sections. The multiple lenses include grooves each provided between the lenses, and the groove includes a bottom surface shaped to protrude downward. Consequently, the bottom surface shaped to protrude downward can suppress degradation of image quality caused by the groove between the lenses.

Moreover, in the first aspect, the groove may include a first portion sandwiched between two adjacent lenses and a second portion sandwiched between four adjacent lenses, and a lower end of the second portion may be located at a position lower than a lower end of the first portion. This enables a groove with a linear planar shape to be provided between two adjacent lenses, while enabling a groove with a point-like planar shape to be provided between four adjacent lenses.

In addition, the solid-state imaging apparatus according to the first aspect may further include a light blocking film provided below the first portion and the second portion. In this case, the groove with the bottom surface shaped to protrude downward can suppress degradation of image quality of the solid-state imaging apparatus caused by light incident on the light blocking film from the groove.

Further, in the first aspect, an upper end of the groove may be an inflexion point of a curvature of a front surface of the lens. This enables, for example, the groove to be formed by etching.

In addition, in the first aspect, a vertical cross section of the bottom surface of the groove may be shaped like a semi-circle, a triangle, or a trapezoid. This enables the bottom surface of the groove to be shaped to protrude downward.

Further, in the first aspect, a vertical end surface of the bottom surface of the groove may be shaped symmetrically with respect to a center line of the vertical cross section of the groove. This enables, for example, light to be evenly directed by the bottom surface of the groove toward multiple color filters around the groove.

In addition, in the first aspect, a width of the groove at a certain height may decrease consistently with the height. This enables, for example, light to be directed by the groove toward the color filters rather than toward the light blocking film.

Further, in the first aspect, a front surface of the groove may include an inflexion point of a curvature located at a position lower than an upper end of the groove but higher than a lower end of the groove. This enables, for example, an increase in the degree of freedom of the shape of the groove.

In addition, in the first aspect, for a slope angle of the front surface of the groove, an angle between the upper end and the inflexion point may be smaller than an angle between the inflexion point and the lower end. This enables, for example, elongation of the vertical cross sectional shape of the groove.

Further, in the first aspect, the slope angle of the front surface of the groove may be smaller than 30 degrees between the upper end and the inflexion point. This enables a reduction in the ratio of the front surface of the groove to the front surface of the lens, allowing suppression of a decrease in light collection rate of the lens caused by the groove.

In addition, in the first aspect, the slope angle of the front surface of the groove may be smaller than 90 degrees between the inflexion point and the lower end. This enables an increase in the light collection rate near the lower end of the groove and also enables suppression of color mixture caused by light near the lower end of the groove.

Further, the solid-state imaging apparatus in the first aspect may further include multiple color filters provided between the multiple photoelectric conversion sections and the multiple lenses, a width of the second portion may be equal to or larger than a distance between the color filters, and a height of the lower end of the second portion may be higher than a height of an upper surface of the color filter. This enables suppression of damage to the color filters when the grooves are formed.

In addition, the solid-state imaging apparatus in the first aspect may further include an anti-reflection film provided on an upper surface of the lens. This enables suppression of reflection of light incident on the lens.

Further, in the first aspect, the anti-reflection film may further be provided on a front surface of the groove. This enables suppression of reflection of light incident into the groove.

In addition, the solid-state imaging apparatus in the first aspect may further include a first film that is provided in the groove and that has a lower refractive index than the lens. This enables suppression of leakage of light from the lens into the groove.

Further, in the first aspect, the first film may further be provided on an upper surface of the lens. This enables, for example, the film provided on the upper surface of the lens to be used as the first film.

In addition, the solid-state imaging apparatus in the first aspect may further include a first film provided on the upper surface of the lens and a second film that is provided in the groove and that has a lower refractive index than the lens. This enables suppression of leakage of light from the lens into the groove.

Further, in the first aspect, the second film may have a lower refractive index than the first film. This enables, for example, suppression of leakage of light from the first film to the second film.

In addition, in the first aspect, the second film may be a glass seal resin for providing glass above the first film. This enables the glass sheet resin to be used as the second film.

Further, the solid-state imaging apparatus in the first aspect may be packaged by WLCSP (Wafer Level Chip Size/Scale Package). This enables, for example, the resin covering the lens to be used as the first film or the second film.

A method for manufacturing a solid-state imaging apparatus according to a second aspect of the present disclosure includes forming multiple photoelectric conversion sections, forming multiple lenses above the multiple photoelectric conversion sections, and forming a groove between the lenses, the groove including a bottom surface shaped to protrude downward. This enables the bottom surface shaped to protrude downward to suppress degradation of image quality caused by the groove between the lenses.

Further, in the second aspect, the groove may include a first portion sandwiched between two adjacent lenses and a second portion sandwiched between four adjacent lenses, and a lower end of the second portion may be formed at a position lower than a lower end of the first portion. This enables a groove with a linear planar shape to be provided between two adjacent lenses, while enabling a groove with a point-like planar shape to be provided between four adjacent lenses.

Further, the method for manufacturing the solid-state imaging apparatus according to the second aspect may include forming an anti-reflection film on an upper surface of the lens and on a front surface of the groove after forming the groove between the lenses. This enables suppression of reflection of light incident on the lens and light in the groove.

In addition, the method for manufacturing the solid-state imaging apparatus according to the second aspect may include forming an anti-reflection film on an upper surface of the lens before forming the groove between the lenses, and the groove may be formed between the lenses such that a hole penetrates the anti-reflection film. This enables suppression of reflection of light incident on the lens and also enables filling of inside of the groove with air or a film other than the anti-reflection film.

Further, the method for manufacturing the solid-state imaging apparatus according to the second aspect may further include forming, in the groove, a first film having a lower refractive index than the lens. This enables suppression of leakage of light from the lens into the groove.

### BRIEF DESCRIPTION OF DRAWINGS

FIG. 1 is a block diagram depicting a configuration of a solid-state imaging apparatus according to a first embodiment.

FIG. 2 is a cross-sectional view depicting a structure of the solid-state imaging apparatus according to the first embodiment.

FIG. 3 is a plan view depicting the structure of the solid-state imaging apparatus according to the first embodiment.

FIG. 4 depicts a plan view and cross-sectional views illustrating the structure of the solid-state imaging apparatus according to the first embodiment.

FIG. 5 depicts cross-sectional views for a comparison between the solid-state imaging apparatus according to the first embodiment and a solid-state imaging apparatus according to a comparative example.

FIG. 6 depicts cross-sectional views illustrating a structure of a solid-state imaging apparatus according to a modified example of the first embodiment.

FIG. 7 is a cross-sectional view depicting a structure of a solid-state imaging apparatus according to another modified example of the first embodiment.

FIG. 8 depicts cross-sectional views illustrating a structure of a solid-state imaging apparatus according to another modified example of the first embodiment.

FIG. 9 depicts cross-sectional views illustrating a structure of a solid-state imaging apparatus according to another modified example of the first embodiment.

FIG. 10 depicts cross-sectional views illustrating a structure of a solid-state imaging apparatus according to another modified example of the first embodiment.

FIG. 11 depicts cross-sectional views (1/4) illustrating a method for manufacturing a solid-state imaging apparatus according to the first embodiment.

FIG. 12 depicts cross-sectional views (2/4) illustrating the method for manufacturing the solid-state imaging apparatus according to the first embodiment.

FIG. 13 depicts cross-sectional views (3/4) illustrating the method for manufacturing the solid-state imaging apparatus according to the first embodiment.

FIG. 14 depicts cross-sectional views (4/4) illustrating the method for manufacturing the solid-state imaging apparatus according to the first embodiment.

FIG. 15 is a cross-sectional view depicting a structure of a solid-state imaging apparatus according to a second embodiment.

FIG. 16 depicts cross-sectional views illustrating a structure of a solid-state imaging apparatus according to a modified example of the second embodiment.

FIG. 17 depicts cross-sectional views illustrating a structure of a solid-state imaging apparatus according to another modified example of the second embodiment.

FIG. 18 depicts cross-sectional views (1/2) illustrating a method for manufacturing a solid-state imaging apparatus according to the second embodiment.

FIG. 19 depicts cross-sectional views (2/2) illustrating the method for manufacturing the solid-state imaging apparatus according to the second embodiment.

FIG. 20 is a cross-sectional view illustrating a structure of a solid-state imaging apparatus according to a third embodiment.

### DESCRIPTION OF EMBODIMENTS

Embodiments of the present invention will be described below with reference to the drawings.

### First Embodiment

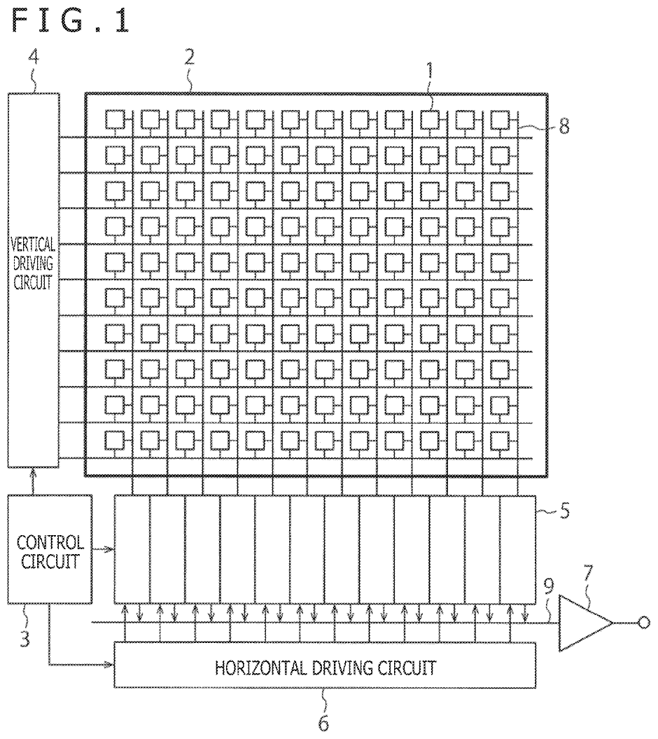

FIG. 1 is a block diagram depicting a configuration of a solid-state imaging apparatus according to a first embodiment.

A solid-state imaging apparatus in FIG. 1 is a CMOS (Complementary Metal Oxide Semiconductor) solid-state imaging apparatus and includes a pixel array region 2 with multiple pixels 1, a control circuit 3, a vertical driving circuit 4, multiple column signal processing circuits 5, a horizontal driving circuit 6, an output circuit 7, multiple vertical signal lines 8, and a horizontal signal line 9.

Each pixel 1 includes a photodiode functioning as a photoelectric conversion section and multiple pixel transistors. As an example, the pixel transistors are four MOS transistors including a transfer transistor, a reset transistor, an amplifying transistor, and a select transistor. However, the pixel transistors may be three MOS transistors corresponding to the four MOS transistors except for the select transistor.

The pixel array region 2 includes multiple pixels 1 arranged in a two-dimensional array. The pixel array region 2 includes an effective pixel region that receives light, performs photoelectric conversion, amplifies signal charge generated by the photoelectric conversion, and outputs the amplified signal charge, and a black reference pixel region (not depicted) for outputting optical black used as a reference for a black level. Typically, the black reference pixel region is disposed at an outer circumferential portion of the effective pixel region.

The control circuit 3 generates various signals corresponding to references for operations of the vertical driving circuit 4, the column signal processing circuits 5, and the horizontal driving circuit 6, according to a vertical synchronization signal, a horizontal synchronization signal, and a master clock. Signals generated by the control circuit 3 include, for example, a clock signal and a control signal and are input to the vertical driving circuit 4, the column signal processing circuits 5, the horizontal driving circuit 6, and the like.

The vertical driving circuit 4 includes, for example, a shift register, and selectively scans the pixels 1 in the pixel array region 2 in units of rows sequentially in the vertical direction. The vertical driving circuit 4 further supplies, to the column signal processing circuit 5 through the vertical signal line 8, a pixel signal based on signal charge generated by each pixel 1 according to the amount of light received.

The column signal processing circuit 5 is, for example, disposed for each column of the pixels 1 in the pixel array region 2, and executes signal processing on signals output from the pixels 1 in one row, for each column, according to a signal from the black reference pixel region. Examples of the signal processing include noise cancellation and signal amplification. At an output stage of the column signal processing circuit 5, a horizontal select switch (not depicted) is provided between the output stage and the horizontal signal line 9.

The horizontal driving circuit 6 includes, for example, a shift register and sequentially outputs horizontal scanning pulses to select the column signal processing circuits 5 in order, to cause each of the column signal processing circuits 5 to output a pixel signal to the horizontal signal line 9.

The output circuit 7 executes signal processing on signals sequentially supplied from the column signal processing circuits 5 through the horizontal signal line 9, and outputs signals subjected to the signal processing.

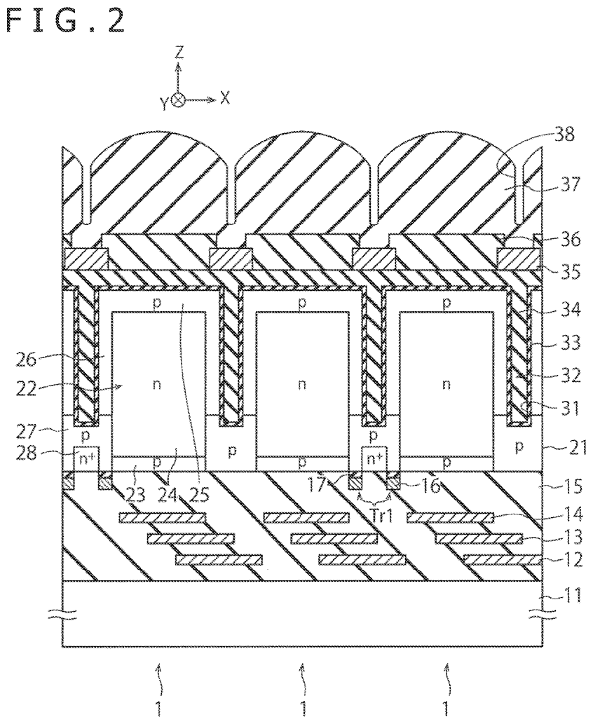

FIG. 2 is a cross-sectional view depicting a structure of the solid-state imaging apparatus according to the first embodiment. FIG. 2 depicts a vertical cross section of the pixel array region 2 in FIG. 1.

The solid-state imaging apparatus according to the present embodiment includes a support substrate 11, multiple wiring layers 12, 13, and 14, an inter-layer insulating film 15, and a gate electrode 16 and a gate insulating film 17 included in each transfer transistor Tr1.

The solid-state imaging apparatus according to the present embodiment includes a substrate 21, multiple photoelectric conversion sections 22 in the substrate 21, a p-type semiconductor region 23, an n-type semiconductor region 24, and a p-type semiconductor region 25 included in each of the photoelectric conversion sections 22, a pixel isolation layer 26 in the substrate 21, a p well layer 27, and multiple floating diffusion portions 28.

The solid-state imaging apparatus according to the present embodiment further includes grooves 31, an element isolation portion 32 provided in the groove 31, a fixed charge film (film having negative fixed charge) 33 and an insulating film 34 included in the element isolation portion 32, a light blocking film 35, multiple color filters 36, multiple on-chip lenses 37, and grooves 38 each between the on-chip lenses 37.

FIG. 2 depicts an X axis, a Y axis, and a Z axis that are perpendicular to one another. The X direction and the Y direction correspond to the lateral direction (horizontal direction), and the Z direction corresponds to the longitudinal direction (vertical direction). Further, a +Z direction corresponds to an upward direction, and a −Z direction corresponds to a downward direction. The −Z direction may precisely align with the direction of gravitational force or may not precisely align with the direction of gravitational force.

The substrate 21 is, for example, a semiconductor substrate such as a silicon (Si) substrate. In FIG. 2, a surface of the substrate 21 in the −Z direction is a front side surface of the substrate 21, and a surface of the substrate 21 in the Z direction is a back side surface (back surface) of the substrate 21. The solid-state imaging apparatus according to the present embodiment is of a back-illuminated type, and hence, the color filters 36 and the on-chip lenses 37 are provided on the back side of the substrate 21 and located on the upper side of the substrate 21 in FIG. 2. The back surface of the substrate 21 corresponds to a light incident surface of the substrate 21. On the other hand, the wiring layers 12 to 14 are provided on the front side of the substrate 21 and are located on the lower side of the substrate 21 in FIG. 2. The substrate 21 has a thickness of, for example, from 1 to 6 μm.

The photoelectric conversion section 22 is provided in the substrate 21 for each pixel 1. FIG. 2 illustrates three photoelectric conversion sections 22 for the respective three pixels 1. Each photoelectric conversion section 22 includes the p-type semiconductor region 23, the n-type semiconductor region 24, and the p-type semiconductor region 25 formed in the substrate 21 in this order from the front side toward the back side of the substrate 21. In the photoelectric conversion section 22, main photodiodes are implemented by pn junction between the p-type semiconductor region 23 and the n-type semiconductor region 24 and pn junction between the n-type semiconductor region 24 and the p-type semiconductor region 25, and the photodiodes convert light into charge. The photoelectric conversion section 22 receives, via the color filters 36, light incident on the on-chip lens 37, generates signal charge according to the amount of light received, and accumulates the generated signal charge in the n-type semiconductor region 24.

The pixel isolation layer 26 is a p-type semiconductor region provided between the photoelectric conversion sections 22 adjacent to each other. The p well layer 27 is a p-type semiconductor region provided on the front side of the substrate 21 with respect to the pixel isolation layer 26. The floating diffusion portion 28 is an n-type semiconductor region provided on the front side of the substrate 21 with respect to the p well layer 27. The floating diffusion portion 28 is formed by doping the p well layer 27 with high concentration of n-type impurities.

Note that the p-type semiconductor region and the n-type semiconductor region in the substrate 21 according to the present embodiment may be replaced with each other. In other words, the p-type semiconductor region 23, the p-type semiconductor region 25, the pixel isolation layer 26, and the p well layer 27 may be changed to n-type semiconductor regions, whereas the n-type semiconductor region 24 and the floating diffusion portion 28 may be changed to p-type semiconductor regions.

The groove 31 is shaped to extend from the back surface of the substrate 21 in a depth direction (−Z direction) and, as is the case with the pixel isolation layer 26, is provided between the photoelectric conversion sections 22 adjacent to each other. The groove 31 is formed by forming a recessed portion in the pixel isolation layer 26 by etching. The groove 31 according to the present embodiment reaches the p well layer 27 but not the floating diffusion portion 28.

The element isolation portion 32 includes the fixed charge film 33 and the insulating film 34 formed in the groove 31 in this order. The fixed charge film 33 is formed on side surfaces and a bottom surface of the groove 31. The insulating film 34 is embedded in the groove 31 via the fixed charge film 33.

The fixed charge film 33 is a film having negative fixed charge and forms a material of the element isolation portion 32. Typically, in the solid-state imaging apparatus, even with no incident light or signal charge, charge may be generated from microdefects present in an interface in the substrate 21. The charge causes noise referred to as a dark current. However, a film having negative fixed charge is effective for suppressing generation of such a dark current. Consequently, according to the present embodiment, the fixed charge film 33 enables a reduction in dark current. The fixed charge film 33 according to the present embodiment is formed all over the back surface of the substrate 21 and is disposed above the photoelectric conversion section 22 as well as in the element isolation portion 32.

The fixed charge film 33 is preferably formed of a material that enables fixed charge to be generated to enhance pinning when the fixed charge film 33 is formed on the substrate 21 such as a silicon substrate. Examples of such a fixed charge film 33 include such insulating films as a high-refractive-index material film and a high dielectric film.

The fixed charge film 33 is, for example, an oxide film or a nitride film containing at least one metal element of hafnium (Hf), aluminum (Al), zirconium (Zr), tantalum (Ta), and titanium (Ti). A method for forming the fixed charge film 33 is, for example, CVD (Chemical Vapor Deposition), sputtering, ALD (Atomic Layer Deposition), or the like. With ALD, in the step of forming the fixed charge film 33, a silicon oxide film corresponding to a film reducing an interface state can be formed to a thickness of approximately 1 nm. Other examples of the fixed charge film 33 include an oxide or a nitride containing at least one metal element of lantern (La), praseodymium (Pr), cerium (Ce), neodymium (Nd), promethium (Pm), samarium (Sm), europium (Eu), gadolinium (Gd), terbium (Tb), dysprosium (Dy), holmium (Ho), thulium (Tm), ytterbium (Yb), lutetium (Lu), and yttrium (Y). Further, the fixed charge film 33 may be a hafnium oxynitride film or an aluminum oxynitride film.

Silicon (Si) or nitrogen (N) may be added into the fixed charge film 33 to such an extent that the insulation property of the fixed charge film 33 is not compromised. This enables the heat resistance and ion implantation inhibition capability of the fixed charge film 33 to be enhanced.

In the present embodiment, the element isolation portion 32 is implemented by the fixed charge film 33 or the like, and an inversion layer is formed on a surface of the element isolation portion 32 that contacts the fixed charge film 33. Consequently, the interface in the substrate 21 is pinned by the inversion layer, suppressing generation of a dark current. In the present embodiment, the grooves 31 are formed in the substrate 21, and thus the side surfaces and the bottom surface of the groove 31 may be physically damaged, possibly leading to unpinning around the groove 31. However, in the present embodiment, the fixed charge film 33 is formed on the side surfaces and the bottom surface of the groove 31, allowing prevention of unpinning.

The insulating film 34, along with the fixed charge film 33, forms a material of the element isolation portion 32. The insulating film 34 is preferably formed of a material having a refractive index different from that of the fixed charge film 33. Examples of such an insulating film 34 include a silicon oxide film, a silicon nitride film, a silicon oxynitride film, resin, and the like. Further, the insulating film 34 may be a film having no positive fixed charge or only a small amount of positive fixed charge. The insulating film 34 according to the present embodiment is formed all over the back surface of the substrate 21 and disposed above the photoelectric conversion section 22 as well as in the element isolation portion 32.

In the present embodiment, the groove 31 is embedded with the insulating film 34 or the like to isolate the photoelectric conversion sections 22 from each other by the insulating film 34 or the like. Consequently, signal charge is less likely to leak from each pixel 1 to the adjacent pixel 1, and hence, in a case where signal charge is generated beyond the amount of charge saturated, the present embodiment can reduce the leakage of the signal charge overflowing the photoelectric conversion section 22, into the adjacent photoelectric conversion section 22. This allows color mixture between the pixels 1 to be suppressed.

The light blocking film 35 is formed in a predetermined region on the insulating film 34 formed on the back surface of the substrate 21, and has the effect of blocking light from the on-chip lens 37. In the pixel array region 2, the light blocking film 35 is formed like a net such that the photoelectric conversion sections 22 are open to the on-chip lenses 37, and is specifically formed above the element isolation portion 32. The light blocking film 35 is a film that is formed of a material blocking light and that contains, for example, such an element as tungsten (W), aluminum (Al), or copper (Cu).

The color filters 36 are formed on the insulating film 34 and on the light blocking film 35 for each pixel 1. For example, the color filters 36 for red (R), green (G), and blue (B) are respectively disposed above the photoelectric conversion sections 22 of the pixels 1 for red, green, and blue. Further, the color filters 36 may include a color filter 36 for infrared light above the photoelectric conversion section 22 of the pixel 1 for infrared light. Each of the color filters 36 has the property of being capable of transmitting light with a predetermined wavelength, and light transmitted through each color filter 36 is incident on the photoelectric conversion section 22 via the insulating film 34 and the fixed charge film 33.

The on-chip lens 37 is formed on each of the color filters 36 for the respective pixels 1. Each on-chip lens 37 has the property of collecting incident light, and the light collected by each on-chip lens 37 is incident on the photoelectric conversion section 22 via the color filters 36, the insulating film 34, and the fixed charge film 33. The on-chip lens 37 is formed of a material through which light is transmitted, and the on-chip lenses 37 according to the present embodiment are connected via the material. Further details of the on-chip lens 37 will be described later.

The grooves 38 are each formed between the on-chip lenses 37 adjacent to each other and extend in the −Z direction. The groove 38 according to the present embodiment is formed by forming, by etching, a recessed portion in the material forming the on-chip lens 37. The groove 38 according to the present embodiment is formed to prevent the on-chip lenses 37 from being cut away. Further, the groove 38 according to the present embodiment is disposed above the element isolation portion 32 and the light blocking film 35 and above the gap between the color filters 36. Further details of the groove 38 will be described later.

The support substrate 11 is provided on the front side of the substrate 21 via the interlayer insulating film 15 and is provided to reserve the strength of the substrate 21. The support substrate 11 is, for example, a semiconductor substrate such as a silicon (Si) substrate.

The wiring layers 12 to 14 are provided in the interlayer insulating film 15 provided on the front side of the substrate 21, and forms a multilayer wiring structure. The multilayer wiring structure according to the present embodiment includes three wiring layers 12 to 14 but may include four or more wiring layers. The wiring layers 12 to 14 include various wires, which are used to drive the pixel transistor of the transfer transistor Tr1 and the like. The wiring layers 12 to 14 are, for example, metal layers containing such an element as tungsten, aluminum, or copper. The interlayer insulating film 15 is, for example, an insulating film including a silicon oxide film or the like.

The gate electrode 16 of each transfer transistor Tr1 is provided below the p well layer 27 between the p-type semiconductor region 23 and the floating diffusion portion 28 via the gate insulating film 17. Each transfer transistor Tr1 can transfer, to the floating diffusion portion 28, the signal charge in the photoelectric conversion section 22. The gate electrode 16 and the gate insulating film 17 are provided in the interlayer insulating film 15.

In the solid-state imaging apparatus according to the present embodiment, the substrate 21 is irradiated with light from the back side, and light enters the on-chip lens 37. The light entering the on-chip lens 37 is collected by the on-chip lens 37 and enters the photoelectric conversion section 22 via the color filters 36 and the like. The photoelectric conversion section 22 performs photoelectric conversion to convert the light into charge, generating signal charge. The signal charge is output as a pixel signal via the vertical signal line 8 in the wiring layers 12 to 14 provided on the front side of the substrate 21.

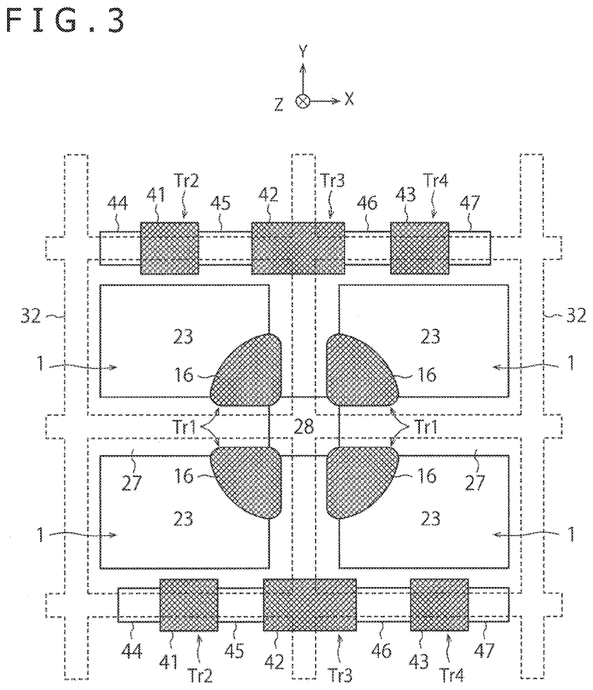

FIG. 3 is a plan view depicting the structure of the solid-state imaging apparatus according to the first embodiment. FIG. 3 depicts a planar structure of the pixel array region 2 in FIG. 1 as viewed from the −Z direction.

In FIG. 3, four pixels 1 share the pixel transistors. FIG. 3 depicts four transfer transistors Tr1, two reset transistors Tr2, two amplifier transistors Tr3, and two select transistors Tr4 shared by the pixels 1.

The transfer transistor Tr1 includes the gate electrode 16 provided on the front side of the substrate 21 via the gate insulating film 17 (FIG. 2). Similarly, the reset transistor Tr2, the amplifier transistor Tr3, and the select transistor Tr4 respectively include gate electrodes 41, 42, and 43 provided on the front side of the substrate 21 via the gate insulating film (not depicted). The solid-state imaging apparatus according to the present embodiment further includes, in the substrate 21, source drain regions 44, 45, 46, and 47 for the reset transistors Tr2, the amplifier transistors Tr3, and the select transistors Tr4. The four types of transistors function as the pixel transistors of the solid-state imaging apparatus according to the present embodiment.

FIG. 3 depicts the p-type semiconductor regions 23 provided for the respective four pixels 1, the p well layer 27 interposed between the p-type semiconductor regions 23, and the floating diffusion portion 28 shared by the four pixels 1. FIG. 3 further depicts the position of the element isolation portion 32 by dot lines. The gate electrodes 16 of the four transfer transistors Tr1 are disposed extending over the corresponding p-type semiconductor region 23 and the floating diffusion portion 28. The transfer transistors Tr1 can transfer, to the floating diffusion portion 28, the signal charge in the corresponding photoelectric conversion section 22.

Further details of the on-chip lens 37 and the groove 38 according to the present embodiment will be described below. In the following description, the on-chip lens 37 is simply referred to as the “lens 37.”

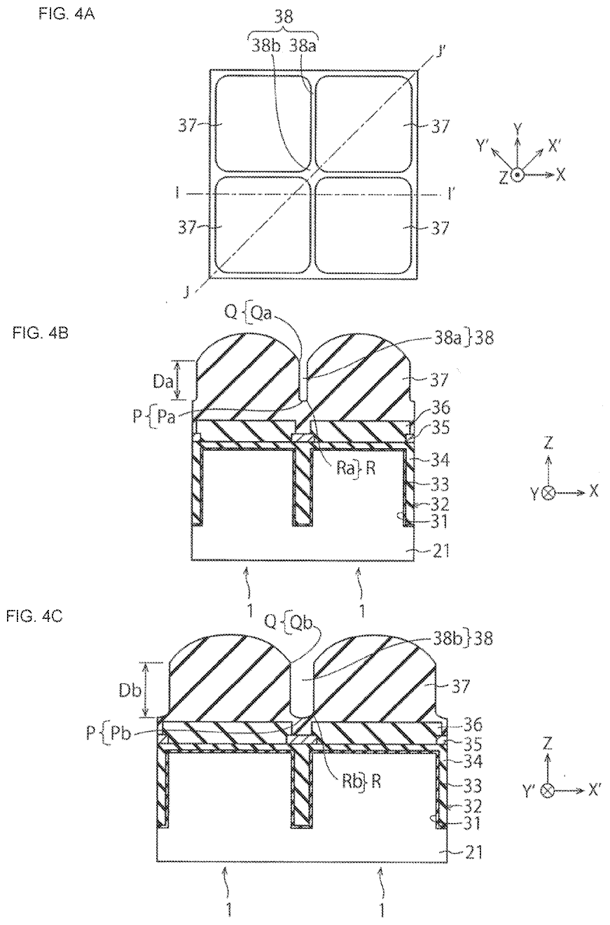

FIG. 4 depicts a plan view and cross-sectional views illustrating the structure of the solid-state imaging apparatus according to the first embodiment.

In FIG. 4, A is a plan view depicting four adjacent lenses 37 of the multiple lenses 37 of the solid-state imaging apparatus according to the present embodiment. The lenses 37 according to the present embodiment are arranged at intersections between multiple straight lines extending in the X direction and multiple straight lines extending in the Y direction, in other words, are arranged in a square lattice. Each of the lenses 37 except those disposed at ends is adjacent to two lenses 37 in ±X directions, to two lenses 37 in ±Y directions, to two lenses 37 in ±X′ directions, and to two lenses 37 in ±Y′ directions. Here, the X′ direction represents a direction inclined at 45 degrees with respect to the X direction, and the Y′ direction represents a direction inclined at 45 degrees with respect to the Y direction.

In FIG. 4, A further illustrates the groove 38 provided between the lenses 37. The groove 38 according to the present embodiment includes a first portion 38a sandwiched between two adjacent lenses 37 and a second portion 38b sandwiched between four adjacent lenses 37. Each of the lenses 37 according to the present embodiment except those disposed at ends is enclosed by four first portions 37a and four second portions 37b. The first portion 38a has a generally linear planar shape, and the second portion 38b has a generally point-like planar shape.

In FIG. 4, B is a cross-sectional view along line I-I′ parallel to the X direction, depicting an XZ cross section of the two lenses 37 adjacent to each other in the ±X direction. In FIG. 4, B depicts a vertical cross-sectional shape of the first portion 38a of the groove 38. The first portion 38a according to the present embodiment is disposed above the element isolation portion 32 and the light blocking film 35 and above the gap between the color filters 36. Note that, in B of FIG. 4, the illustration of the photoelectric conversion sections 22 and the like, depicted in FIG. 2, is omitted (this also applies to the figures described below).

In FIG. 4, C is a cross-sectional view along line J-J′ parallel to the X′ direction, depicting an X′Z cross section of the two lenses 37 adjacent to each other in the ±X′ direction. In FIG. 4, C depicts a vertical cross-sectional shape of the second portion 38b of the groove 38. As the first portion 38a, the second portion 38b according to the present embodiment is disposed above the element isolation portion 32 and the light blocking film 35 and above the gap between the color filters 36.

The groove 38 according to the present embodiment is exposed to the air. Hence, the material forming the lens 37 has a higher refractive index than the substance in the groove 38 (that is, air), making light less likely to leak from the lens 37 into the groove 38. Consequently, the present embodiment can restrain light incident on the lens 37 of one pixel 1 from entering the lens 37 of another pixel 1, which would otherwise cause color mixture. On the other hand, the light can easily enter the lens 37 from the groove 38. Note that the groove 38 may be embedded with a material having a lower refractive index than the material forming the lens 37 as described later.

Further, the groove 38 according to the present embodiment includes a bottom surface shaped to protrude downward as depicted in B and C of FIG. 4. Consequently, according to the present embodiment, light incident on the bottom surface of the groove 38 can be directed toward the color filters 36 rather than toward the light blocking film 35, enabling suppression of degradation of image quality caused by the groove 38. Details of this effect will be described later. Note that a vertical cross section of the bottom surface of the groove 38 according to the present embodiment is semi-circular. This makes the bottom surface of the groove 38 shaped to protrude downward.

In FIGS. 4, B and C depict a lower end P of the groove 38. The lower end P of the groove 38 corresponds to a point where the front surface of the groove 38 has the minimum height. The lower end P of the groove 38 according to the present embodiment is located at the lower end of the bottom surface shaped to protrude downward.

In FIGS. 4, B and C further depict an upper end Q of the groove 38. The upper end Q of the groove 38 according to the present embodiment corresponds to an inflexion point (inflection line) of a curvature of the front surface of the lens 37, and more specifically, to a curvature of one or more curvatures of the front surface of the lens 37 which is closest to the apex of the lens 37. The groove 38 according to the present embodiment corresponds to a space provided between the upper end Q and the lower end P between the lenses 37.

In FIGS. 4, B and C further depict an upper end R of the bottom surface shaped to protrude downward. The groove 38 according to the present embodiment includes a bottom surface shaped to protrude downward, between the upper end R and the lower end P between the lenses 37. The upper end R does not correspond to an inflexion point in B and C of FIG. 4 but may form an inflexion point as the upper end Q.

The groove 38 according to the present embodiment includes a bottom surface shaped to protrude downward both in the first portion 38a and the second portion 38b. However, the groove 38 according to the present embodiment is formed such that a lower end Pb of the second portion 38b is lower than a lower end Pa of the first portion 38a. Thus, a depth Db of the second portion 38b is larger than a depth Da of the first portion 38a. This is because when the first portion 38a and the second portion 38b of the groove 38 are simultaneously formed by etching, the second portion 38b naturally becomes deeper than the first portion 38a due to the characteristics of etching. Note that the depth Db of the second portion 38b may be larger than the depth Db of the first portion 38a due to another cause or may be the same as the depth Da of the first portion 38b.

The depth Da of the first portion 38a corresponds to the distance between the lower end Pa of the first portion 38a and an upper end Qa of the first portion 38a in the Z direction, and the depth Db of the second portion 38b corresponds to the distance between the lower end Pb of the second portion 38b and an upper end Qb of the second portion 38b in the Z direction. In B and C of FIG. 4, the upper end Qa of the first portion 38a is at the same height (Z coordinate) as that of the upper end Qb of the second portion 38b, but the upper end Qa and the upper end Qb may be at different heights. Note that in this regard, the upper end Qa of the first portion 38a and the upper end Qb of the second portion 38b correspond to inflexion points because the groove 38 is formed by etching but the upper end Qa and the upper end Qb need not correspond to inflexion points.

In FIGS. 4, B and C depict, as the upper end R of the bottom surface shaped to protrude downward, an upper end Ra of the bottom surface of the first portion 38a and an upper end Rb of the bottom surface of the second portion 38b. In B and C of FIG. 4, the upper end Ra of the bottom surface of the first portion 38a is at the same height (Z coordinate) as that of the upper end Rb of the bottom surface of the second portion 38b, but the upper end Ra and the upper end Rb may be at different heights.

Note that a vertical cross section of the bottom surface of the groove 38 according to the present embodiment is semi-circular both in the first portion 38a and the second portion 38b. However, the bottom surface of the first portion 38a according to the present embodiment is shaped like a semi-cylinder, whereas the bottom surface of the second portion 38b according to the present embodiment is shaped like a semi-circle. Note that the vertical cross section of the bottom surface of the groove 38 according to the present embodiment may be have a shape other than a semi-circle as described later.

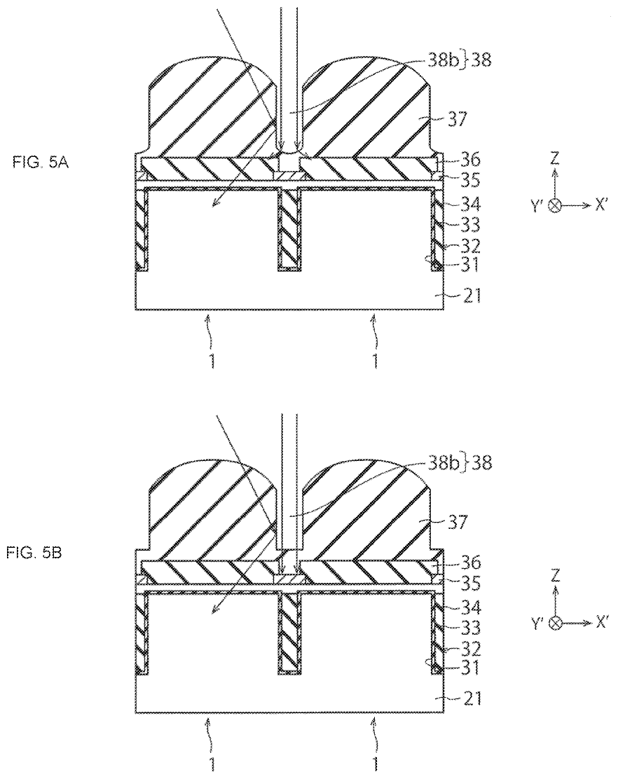

FIG. 5 depicts cross-sectional views for a comparison between the solid-state imaging apparatus according to the first embodiment and a solid-state imaging apparatus according to a comparative example.

In FIG. 5, A depicts a vertical cross section of the solid-state imaging apparatus according to the present embodiment, specifically illustrating an X′Z cross section as in C of FIG. 4. The groove 38 according to the present embodiment includes the bottom surface shaped to protrude downward as described above.

In FIG. 5, B depicts a vertical cross section of a solid-state imaging apparatus according to a comparative example, specifically illustrating an X′Z cross section. The solid-state imaging apparatus according to the comparative example has a structure similar to that of the solid-state imaging apparatus according to the present embodiment except in that the groove 38 according to the comparative example includes a bottom surface having a flat shape.

The solid-state imaging apparatus according to the present embodiment will be compared with the solid-state imaging apparatus according to the comparative example below.

The groove 38 according to the present embodiment (A of FIG. 5) is exposed to the air. Hence, the material forming the lens 37 has a higher refractive index than the substance in the groove 38 (that is, air), making light less likely to leak from the lens 37 into the groove 38. Consequently, the present embodiment can restrain light incident on the lens 37 of one pixel 1 from entering the lens 37 of another pixel 1, which would otherwise cause color mixture. In A of FIG. 5, light directed from the lens 37 toward the groove 38 is reflected at the side surface of the groove 38 by a total reflection mode.

This also applies to the groove 38 according to the comparative example (B of FIG. 5). In B of FIG. 5, light directed from the lens 37 toward the groove 38 is reflected at the side surface of the groove 38 by the total reflection mode.

However, the groove 38 according to the comparative example (B of FIG. 5) includes a bottom surface having a flat shape. Hence, light incident on the bottom surface of the groove 38 enters an upper surface of the light blocking film 35 provided below the groove 38 as depicted in B of FIG. 5. This may cause the light blocking film 35 to absorb light, reducing the sensitivity of the solid-state imaging apparatus. Further, the light blocking film 35 reflects the light, causing stray light or flare. With the groove 38 provided between the adjacent lenses 37 as described above, light may enter the light blocking film 35 from the groove 38 and degrade the image quality of the solid-state imaging apparatus. This problem may be more serious when the size of the pixel 1 is reduced, with the size of the groove 38 increased relative to the size of the lens 37. Note that this problem may also occur in a case where light is absorbed or reflected by a film other than the light blocking film 35.

On the other hand, the groove 38 according to the present embodiment (A of FIG. 5) includes the bottom surface shaped to protrude downward. Thus, according to the present embodiment, as illustrated in A of FIG. 5, light incident on the bottom surface of the groove 38 can be directed toward the color filters 36 rather than toward the light blocking film 35 due to a reverse lens effect, enabling suppression of degradation of image quality caused by the groove 38. This effect can be obtained by the first portion 38a of the groove 38 as well as by the second portion 38b of the groove 38.

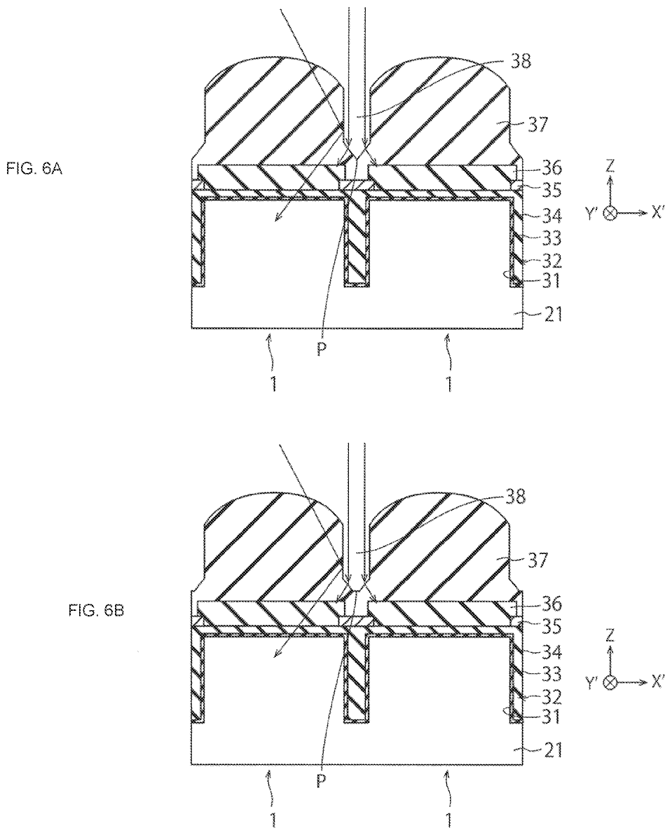

With reference to FIGS. 6 to 10, structures of solid-state imaging apparatuses according to various modified examples of the present embodiment will be described below. The description below focuses on the second portion 38b of the groove 38. However, the present description also applies to the first portion 38a of the groove 38 unless otherwise noted (this also applies to second and third embodiments described below).

FIG. 6 depicts cross-sectional views illustrating a structure of a solid-state imaging apparatus according to a modified example of the first embodiment.

In the modified example illustrated in A of FIG. 6, the bottom surface of the groove 38 is shaped to protrude downward as is the case with C of FIG. 4. However, a vertical cross section of the bottom surface of the groove 38 according to the modified example is triangular as depicted in A of FIG. 6. This enables light incident on the bottom surface of the groove 38 to be directed toward the color filters 36 rather than toward the light blocking film 35.

In a modified example depicted in B of FIG. 6, the bottom surface of the groove 38 is also shaped to protrude downward as is the case with C of FIG. 4. However, a vertical cross section of the bottom surface of the groove 38 according to the present modified example is shaped like a trapezoid as depicted in B of FIG. 6. This enables light incident on the bottom surface of the groove 38 to be directed toward the color filters 36 rather than toward the light blocking film 35. Note that in the present modified example, light incident on an upper base of the trapezoid (a flat surface of the groove 38) may be incident on the upper surface of the light blocking film 35. However, the flat surface of the groove 38 according to the modified example can be made smaller than the flat surface of the groove 38 according to the comparative example. Thus, compared to the comparative example, the present modified example enables suppression of degradation of image quality caused by the groove 38.

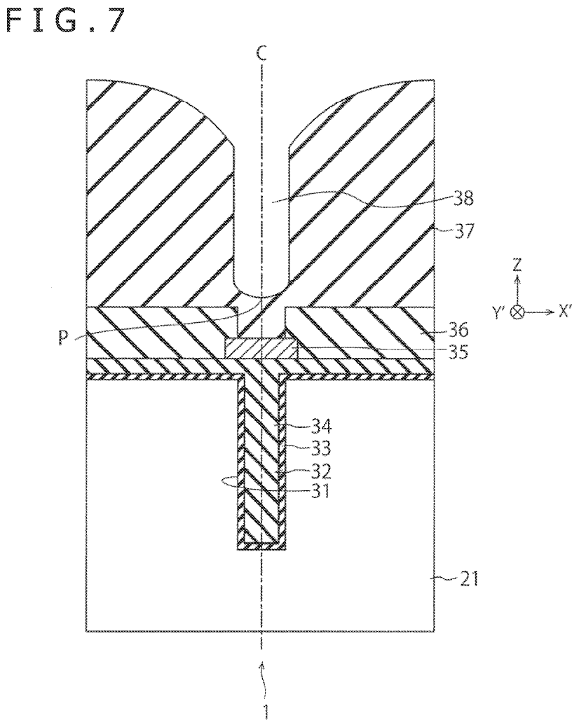

FIG. 7 is a cross-sectional view depicting a structure of a solid-state imaging apparatus according to another modified example of the first embodiment.

In the modified example depicted in FIG. 7, a vertical cross section of the bottom surface of the groove 38 is shaped symmetrically with respect to a center line C of the vertical cross section of the groove 38. Thus, according to the present modified example, the bottom surface of the groove 38 enables light to be evenly directed toward the multiple color filters 36 around the groove 38. For example, each first portion 38a enables light to be evenly directed toward two color filters 36 around the first portion 38a, whereas each second portion 38b enables light to be evenly directed toward four color filters 36 around the second portion 38b. This enables a reduction in difference in sensitivity among the pixels 1.

Note that the bottom surface of each first portion 38 according to the present modified example is shaped reflection-symmetrically with respect to a central surface. In this case, the center line C described above is located on the central surface. On the other hand, the bottom surface of each second portion 38 according to the present modified example is shaped rotation-symmetrically with respect to the center line C.

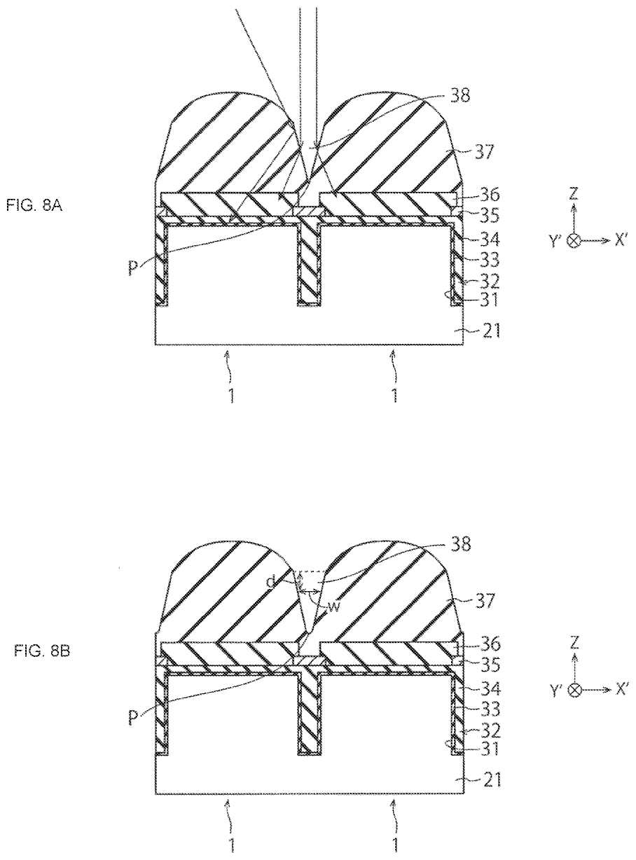

FIG. 8 depicts cross-sectional views illustrating a structure of a solid-state imaging apparatus according to another modified example of the first embodiment.

In the modified example depicted in A of FIG. 8, the entire front surface of the groove 38 forms the bottom surface of the groove 38, and a vertical cross section of the bottom surface is shaped like a triangle. Specifically, the front surface of the groove 38 according to the present modified example has a reversely tapered shape. This enables light incident on the groove 38 to be directed toward the color filters 36 rather than toward the light blocking film 35.

In the modified example depicted in B of FIG. 8 as well, the entire front surface of the groove 38 forms the bottom surface of the groove 38, and a vertical cross section of the bottom surface is shaped like a triangle. Specifically, a vertical cross section of the bottom surface is shaped like a triangle with one rounded corner. The front surface of the groove 38 according to the modified example also has a reversely tapered shape. This enables light incident on the groove 38 to be directed toward the color filters 36 rather than toward the light blocking film 35.

In FIG. 8, B depicts a width w of the groove 38 at a certain height (depth) d. In the present modified example, the width w of the groove 38 at the certain height d decreases consistently with the height d. This makes the front surface of the groove 38 tapered. Such a relation between the height d and the width w is also established in A of FIG. 8.

Note that in A and B of FIG. 8, the width w corresponds to a “monotonically decreasing function of the depth d” that decreases with increasing depth d but the width w may correspond to a “decreasing function of the height d” that decreases or remains constant with increasing depth d as depicted in C of FIG. 4. Specifically, the front surface of the groove 38 may be formed exclusively by an inclined surface or by an inclined surface and a perpendicular surface.

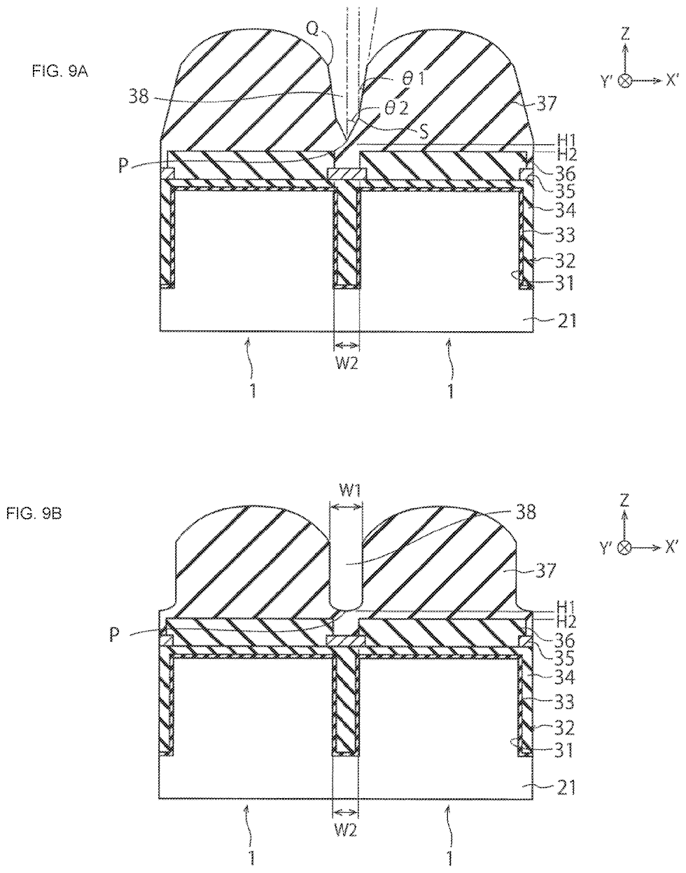

FIG. 9 depicts cross-sectional views illustrating a structure of a solid-state imaging apparatus according to another modified example of the first embodiment.

In the modified example depicted in A of FIG. 9, the entire front surface of the groove 38 forms the bottom surface of the groove 38, and a vertical cross section of the bottom surface is shaped like a triangle. Specifically, the vertical cross section of the bottom surface is shaped like one in which a triangle is changed to a pentagon. The front surface of the groove 38 according to the present modified example also has a reversely tapered shape. This enables light incident on the groove 38 to be directed toward the color filters 36 rather than toward the light blocking film 35. The groove 38 according to the present modified example includes an inflexion point corresponding to an upper end Q of the groove 38 and an inflexion point S located at a position lower than the upper end Q but higher than a lower end P. Such an inflexion point S provided on the front surface of the groove 38, for example, enables an increase in the degree of freedom of the shape of the groove 38.

In FIG. 9, A depicts, as slope angles of the front surface of the groove 38, a slope angle θ1 between the upper end Q and the inflexion point S and a slope angle θ2 between the inflexion point S and the lower end P. The slope angles θ1 and θ2 have a relation of 0°<θ1<θ2<90°. This enables, for example, elongation of the vertical cross-sectional shape of the groove 38.

The slope angle θ1 is desirably prevented from being excessively large and is desirably greater than 0° but equal to or smaller than 30° (0°<θ1≤30°). This is because a slope angle θ1 greater than 30° increases the ratio of the front surface of the groove 38 to the front surface of the lens 37, making the lens 37 approximate to a triangular lens. The lens 37 approximate to a triangular lens may reduce the light collection rate of the lens 37, decreasing the sensitivity of the solid-state imaging apparatus.

On the other hand, the slope angle θ2 may be any angle between 0° and 90° (0°<θ2<90°) as long as the slope angle θ2 is greater than the slope angle θ1. A slope angle θ2 of 90° prevents the light collection effect from being achieved at the bottom surface near the lower end P. Thus, the slope angle θ2 is desirably less than 90° rather than being 90°. Further, a slope angle θ2 greater than 90° makes the bottom surface shaped to protrude upward near the lower end P, and thus light incident on a certain pixel 1 is not collected on the pixel 1 but on another pixel 1 near the lower end P. This leads to color mixture between the pixels 1, and thus the slope angle θ2 is desirably less than 90° rather than being greater than 90°.

Note that the condition of “0°<θ1≤30°” for the slope angle θ1 can also be applied to the bottom surface of the triangle in A of FIG. 8 and to the bottom surface of the triangular portion in B of FIG. 8.

In a modified example depicted in B of FIG. 9, a width W1 of the groove 38 (second portion 38b) is equal to or greater than a distance W2 between adjacent color filters 36 (W1≥W2). In this case, in a case where the groove 38 is excessively deep, the groove 38, when formed by etching, may reach and damage the color filter 36.

As such, in B of FIG. 9, a height H1 of the lower end P of the groove 38 (second portion 38b) is greater than a height H2 of the upper surface of the color filter 36 (H1>H2). In other words, before the groove 38 reaches the color filter 36, etching of the groove 38 is finished. This enables suppression of damage to the color filters 36 when the grooves 38 are formed.

Note that the modified example depicted in B of FIG. 9 can be applied both to the first portion 38a and the second portion 38b of the groove 38. However, in many cases, the second portion 38b is deeper than the first portion 38a, and thus the modified example depicted in B of FIG. 9 is expected to be mainly applied to the second portion 38b.

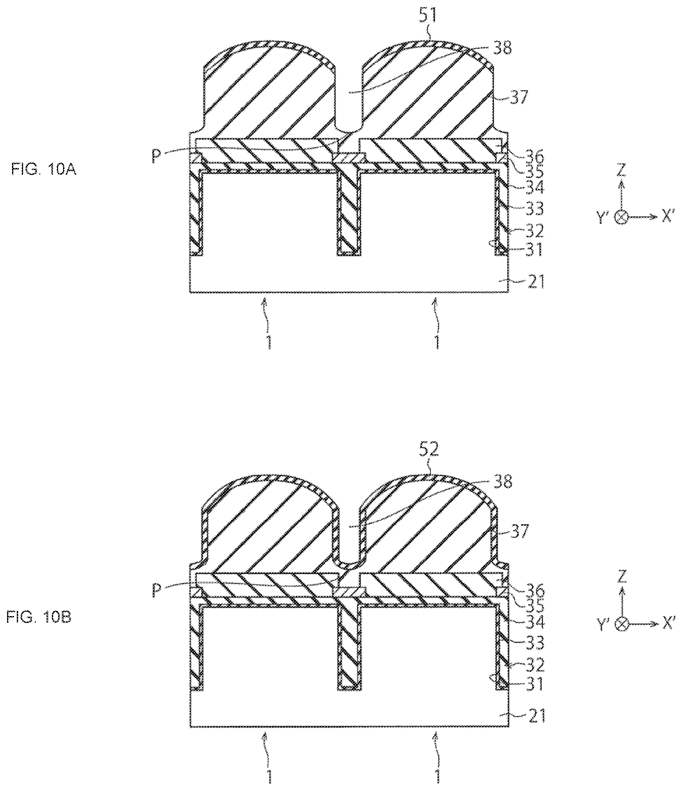

FIG. 10 depicts cross-sectional views illustrating a structure of a solid-state imaging apparatus according to another modified example of the first embodiment.

A solid-state imaging apparatus according to a modified example depicted in A of FIG. 10 includes an anti-reflection film 51 formed on the upper surface of the lens 37. This enables suppression of reflection of light incident on the lens 37. The anti-reflection film 51 according to the present modified example is formed on the upper surface of the lens 37 but not on the front surface of the groove 38. Such an anti-reflection film 51 can be formed by, for example, forming the anti-reflection film 51 on each of the lenses 37 and then forming the groove 38 between the lenses 37 such that a hole penetrates the anti-reflection film 51.

A solid-state imaging apparatus according to a modified example depicted in B of FIG. 10 includes an anti-reflection film 52 formed on the upper surface of the lens 37 and on the front surface of the groove 38. This enables suppression of reflection of light incident on the lens 37 and the groove 38. Such an anti-reflection film 52 can be formed by, for example, forming the groove 38 between the lenses 37 and then forming the anti-reflection film 52 on the upper surface of the lens 37 and on the front surface of the groove 38. Note that in a case where the present modified example is combined with another modified example for implementation, the shape and size of the groove 38 are dealt in a state in which the anti-reflection film 52 is not provided.

Examples of the anti-reflection films 51 and 52 include a silicon oxide film and a silicon nitride film. A solid-state imaging apparatus according to the present embodiment may include the anti-reflection film 51 depicted in FIG. 10A or the anti-reflection film 52 depicted in FIG. 10B

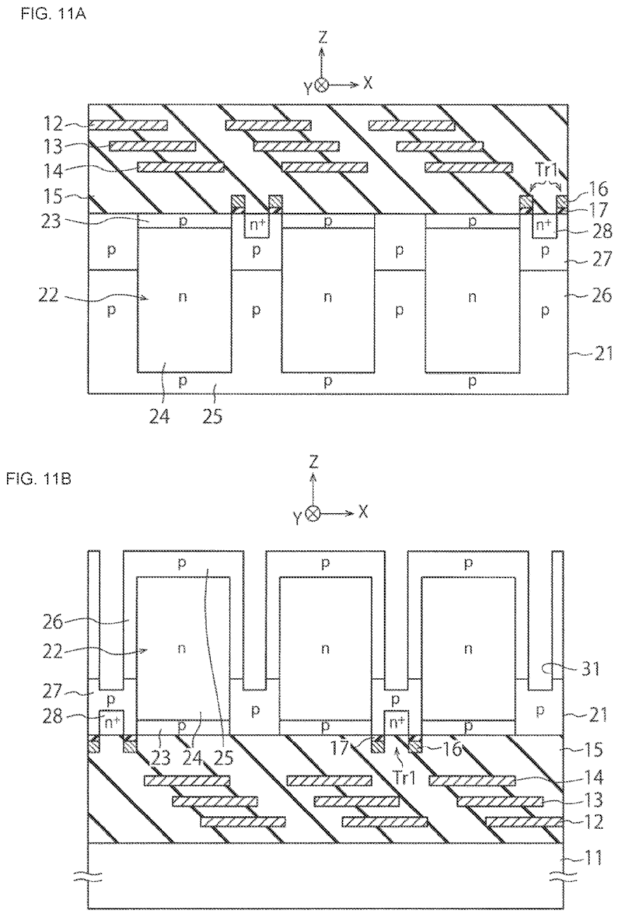

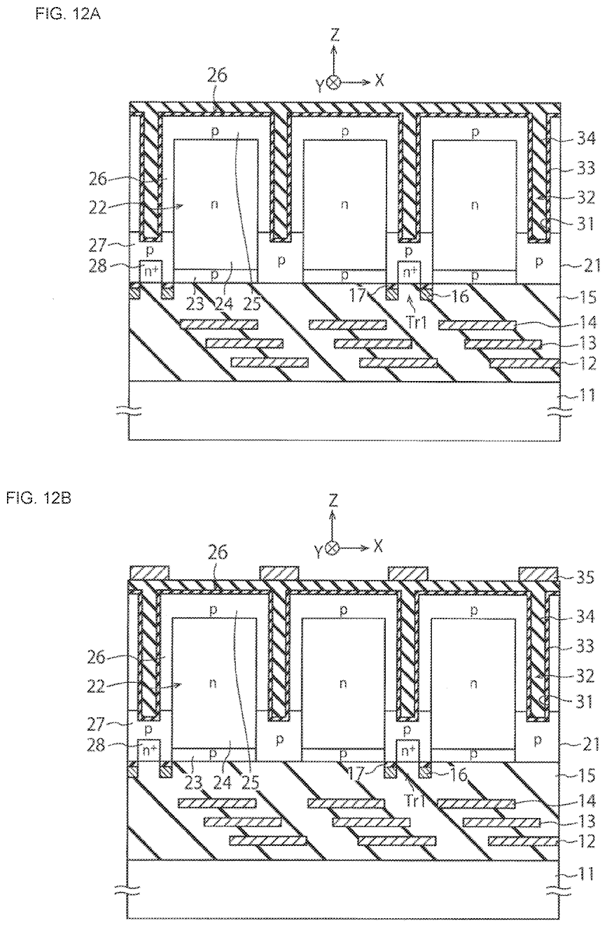

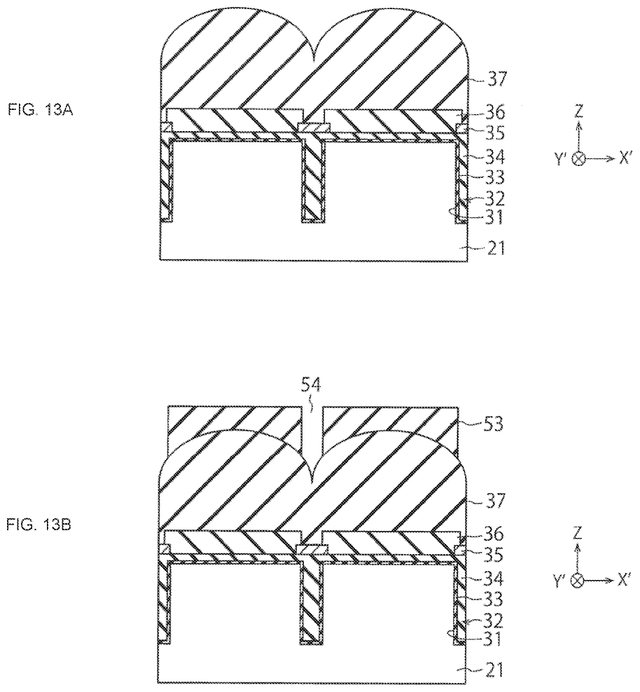

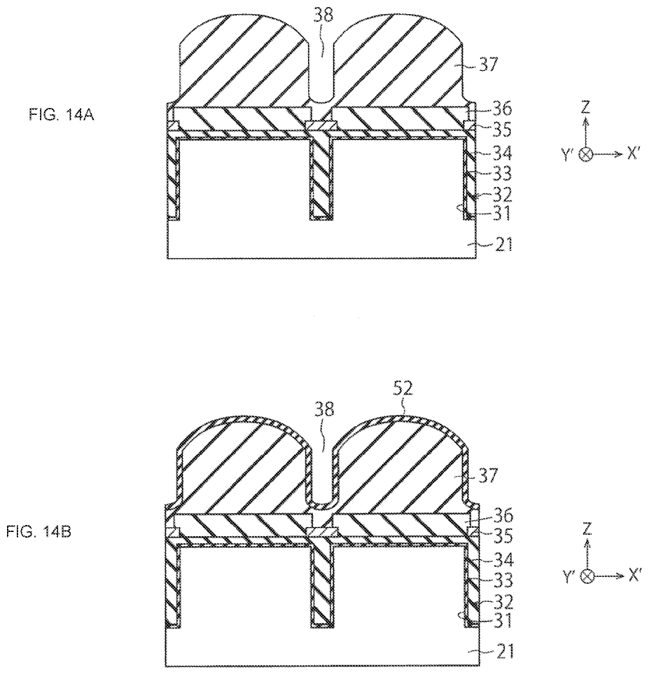

FIGS. 11 to 14 are cross-sectional views depicting a method for manufacturing a solid-state imaging apparatus according to the first embodiment. Depicted in A of FIG. 11 to B of FIG. 12 is an XZ cross section of a solid-state imaging apparatus according to the present embodiment, and depicted in A of FIG. 13 to B of FIG. 14 is an X′Z cross section of the solid-state imaging apparatus according to the present embodiment.

First, as depicted in A of FIG. 11, the following are formed in and on the substrate 21: the p-type semiconductor region 23, the n-type semiconductor region 24, the p-type semiconductor region 25, the pixel isolation layer 26, the p well layer 27, the floating diffusion portion 28, the gate insulating film 17, the gate electrode 16, and the like. At this stage, also formed are the gate insulating film, the gate electrodes 41 to 43, and the source drain regions 44 to 47 which are used for the reset transistors Tr2, the amplifier transistors Tr3, and the select transistors Tr4. In such a manner, the photoelectric conversion sections 22 and the pixel transistors are formed. Then, as depicted in A of FIG. 11, the interlayer insulating film 15 and the wiring layers 12 to 14 are alternately formed on the front side of the substrate 21. Note that the step in A of FIG. 11 is executed with the front side of the substrate 21 facing upward and the back side of the substrate 21 facing downward.

Subsequently, as depicted in B of FIG. 11, the support substrate 11 is bonded to the front side of the substrate 21 via the interlayer insulating film 15, and then the substrate 21 is turned upside down. In FIG. 11, B depicts the substrate 21 with the front side facing downward and the back side facing upward.

Then, as depicted in B of FIG. 11, the substrate 21 is thinned from the back surface, and the grooves 31 are formed in the substrate 21 to a predetermined depth by etching. The grooves 31 are formed in the pixel isolation layer 26 from the back surface of the substrate 21. In view of spectral characteristics, the depth of the groove 31 is preferably 0.2 μm or more and more preferably 1.0 μm or more from the back surface of the substrate 21. Further, in view of spectral characteristics, the width of the groove 31 is preferably 0.02 μm or more. Setting a large width of the groove 31 facilitates processing of the groove 31. However, a larger width of the groove 31 indicates inferior spectral characteristics and a smaller amount of saturation charge, and thus the width of the groove 31 is more desirably approximately 0.02 μm. The groove 31 according to the present embodiment is formed to a depth at which the groove 31 reaches the p well layer 27 but not the floating diffusion portion 28 and the source drain regions 44 to 47.

Next, as depicted in A of FIG. 12, the fixed charge film 33 and the insulating film 34 are formed on the back surface of the substrate 21 in this order. As a result, the fixed charge film 33 is formed on the side surfaces and bottom surface of the groove 31 and on the photoelectric conversion section 22. Further, the insulating film 34 is embedded in the groove 31 via the fixed charge film 33 and is formed on the photoelectric conversion section 22 via the fixed charge film 33. In such a manner, the element isolation portion 32 is formed in the groove 31. The fixed charge film 33 is formed by, for example, CVD, sputtering, or ALD. The insulating film 34 is formed by, for example, CVD.

Then, as depicted in B of FIG. 12, the light blocking film 35 is formed in a predetermined region on the insulating film 34 formed on the back surface of the substrate 21. The light blocking film 35 is formed by, for example, forming a material layer of the light blocking film 35 on the insulating film 34 and patterning the material layer into a predetermined shape. The light blocking film 35 according to the present embodiment is formed above the element isolation portion 32.

Then, as depicted in A of FIG. 13, the multiple color filters 36 and the multiple lenses 37 are formed in this order on the insulating film 34 and the light blocking film 35. As a result, the color filter 36 and the lens 37 are formed in this order above the photoelectric conversion section 22.

Then, as depicted in B of FIG. 13, a resist film 53 is formed on the lenses 37, and a groove 54 is formed in the resist film 53 by lithography and etching. The groove 54 in the resist film 53 is each formed on a region between the lenses 37 in which the groove 38 is to be formed.

Then, as depicted in A of FIG. 14, the material forming the lens 37 is processed by dry etching using the resist film 53 as a mask. As a result, the groove 54 in the resist film 53 is transferred to the material, forming the groove 38 between the lenses 37. The groove 38 is formed between two adjacent lenses 37 or between four adjacent lenses 37. Thus, the groove 38 that includes the first portion 38a and the second portion 38b described above is formed. Subsequently, the resist film 53 is removed.

The groove 38 according to the present embodiment is formed such that the bottom surface of the groove 38 is shaped to protrude downward. Such a groove 38 can be formed by, for example, performing defocusing during exposure of the resist film 53 such that the front surface of the groove 54 in the resist film 53 is reversely tapered. Note that the groove 38 shaped to protrude downward may be formed using any other method. As described above, a solid-state imaging apparatus depicted in A to C of FIG. 4 is manufactured.

Subsequently, as depicted in B of FIG. 14, the anti-reflection film 52 described above may be formed all over the substrate 21. As a result, the anti-reflection film 52 is formed on the upper surface of the lens 37 and on the front surface of the groove 38, manufacturing a solid-state imaging apparatus depicted in B of FIG. 10. Note that when the solid-state imaging apparatus depicted in A of FIG. 10 is manufactured, the anti-reflection film 51 is formed on the upper surface of the lens 37 after the step in A of FIG. 13, and in the step in A of FIG. 14, the groove 38 is formed between the lenses 37 such that a hole penetrates the anti-reflection film 51.

Note that the groove 38 according to the present embodiment includes a bottom surface shaped to protrude downward both in the first portion 38a and the second portion 38b. However, the groove 38 according to the present embodiment is formed such that the lower end Pb of the second portion 38b is lower than the lower end Pa of the first portion 38a. Thus, the depth Db of the second portion 38b is greater than the depth Da of the first portion 38a (see A to C of FIG. 4). This is because when, in the step in A of FIG. 14, the first portion 38a and the second portion 38b of the groove 38 are simultaneously formed by etching, the second portion 38b is naturally formed deeper than the first portion 38a due to the characteristics of etching. Note that the depth Db of the second portion 38b may be greater than the depth Db of the first portion 38a for another reason or may be the same as the depth Da of the first portion 38b.

As described above, the lens 37 according to the present embodiment includes the groove 38 provided between the lenses 37, and the groove 38 includes the bottom surface shaped to protrude downward. Thus, according to the present embodiment, the bottom surface shaped to protrude downward can suppress degradation of image quality caused by the groove 38 between the lenses 37.

### Second Embodiment

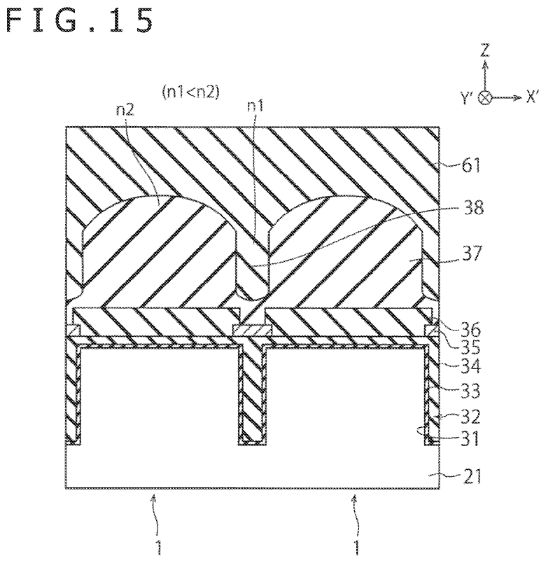

FIG. 15 is a cross-sectional view depicting a structure of a solid-state imaging apparatus according to a second embodiment. As C of FIG. 4, FIG. 15 depicts an X′Z cross section of the solid-state imaging apparatus according to the present embodiment.

The solid-state imaging apparatus according to the present embodiment includes a planarization film 61 provided on the upper surface of the lens 37 and in the groove 38, in addition to the components of the solid-state imaging apparatus according to the first embodiment depicted in FIG. 2, FIG. 4A, FIG. 4B, FIG. 4C, and the like. The planarization film 61 according to the present embodiment is formed all over the substrate 21, covering the lenses 37 and the grooves 38, and thus planarizing the surface on the back surface of the substrate 21. The planarization film 61 is an example of a first film according to the present disclosure.

The planarization film 61 according to the present embodiment has a refractive index n1 lower than a refractive index n2 of the lens 37 (n1<n2). For example, the refractive index n1 of the planarization film 61 is lower than 1.5, and the refractive index n2 of the lens 37 is higher than 1.5. The material forming the lens 37 is, for example, a silicon oxide film, a silicon nitride film, a silicon oxynitride film, a titanium oxide film, an acrylic resin, or the like. The planarization film 61 is, for example, a resin containing a filler of silicon oxide, siloxane, or the like. The siloxane may contain fluorine. The fluorine-containing siloxane has a refractive index ranging, for example, from 1.15 to 1.45.

According to the present embodiment, the planarization film 61 having the refractive index n1 lower than the refractive index n2 of the lens 37 is provided in the groove 38. This allows light to be made less likely to leak from the lens 37 into the groove 38 as in the case in which the groove 38 is exposed to the air. Accordingly, the present embodiment can restrain light incident on the lens 37 of one pixel 1 from entering the lens 37 of another pixel 1, which would otherwise cause color mixture. On the other hand, light can easily enter the lens 37 from the groove 38.

Note that in the present embodiment, the film formed in the groove 38 is the planarization film 61 formed on the upper surface of the lens 37 but a film other than the planarization film 61 may be formed in the groove 38 as described later. However, according to the present embodiment, the planarization film 61 is formed in the groove 38, allowing saving of the need to execute the step of forming a film in the groove 38 separately from the step of forming the planarization film 61.

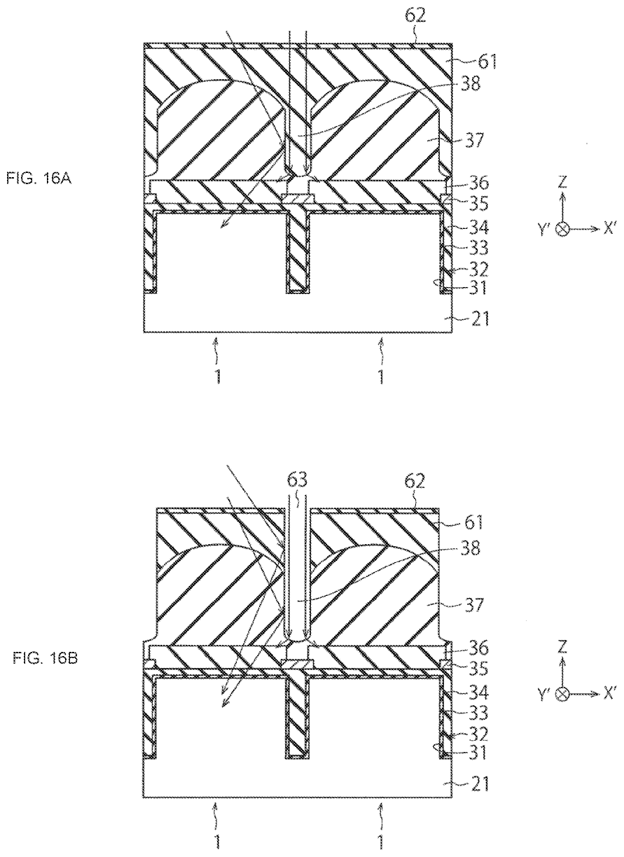

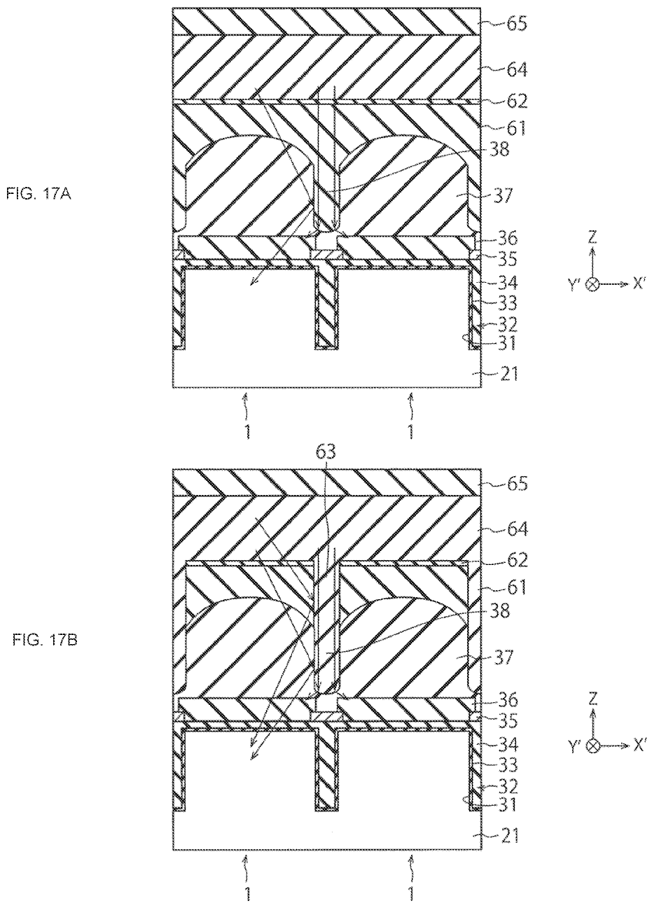

With reference to FIGS. 16 and 17, structures of solid-state imaging apparatuses according to various modified examples of the present embodiment will be described below.

FIG. 16 depicts cross-sectional views illustrating a structure of a solid-state imaging apparatus according to a modified example of the second embodiment.

In the modified example depicted in A of FIG. 16, the planarization film 61 is formed on the upper surface of the lens 37 and in the groove 38 as is the case with FIG. 16. In FIG. 16, A further depicts a cover film 62 provided on the planarization film 61.

In the present modified example, the refractive index n1 of the planarization film 61 is lower than the refractive index n2 of the lens 37, making light less likely to leak from the lens 37 into the groove 38. In A of FIG. 16, light traveling from the lens 37 toward the groove 38 is reflected by the side surface of the groove 38 due to the total reflection mode.

Further, in the present modified example, the bottom surface of the groove 38 is shaped to protrude downward. Thus, according to the present modified example, as depicted in A of FIG. 16, light incident on the bottom surface of the groove 38 can be directed toward the color filters 36 rather than toward the light blocking film 35 due to the reverse lens effect, enabling suppression of degradation of image quality caused by the groove 38.

A solid-state imaging apparatus according to a modified example depicted in B of FIG. 16 includes the groove 38 provided between the lenses 37 and a groove 63 penetrating the planarization film 61 and the cover film 62. The groove 63 is provided above the groove 38 and forms one groove with the groove 38. The grooves 38 and 63 can be formed by forming, by etching in the same step, grooves (grooves 38 and 63) penetrating the lens 37, the planarization film 61, and the cover film 62 as described below. However, the grooves 38 and 63 may be formed in different steps.

The grooves 38 and 63 according to the present modified example are exposed to the air, and thus light is less likely to leak from the lens 37 into the groove 38 and to further leak from the planarization film 61 and the cover film 62 into the groove 63. In B of FIG. 16, light traveling from the lens 37 toward the groove 38 is reflected by the side surface of the groove 38 due to the total reflection mode, and light traveling from the planarization film 61 toward the groove 63 is reflected by the side surface of the groove 63 due to the total reflection mode.

Furthermore, in the present modified example, the bottom surface of the groove 38 is shaped to protrude downward. Thus, according to the present modified example, as depicted in B of FIG. 16, light incident on the bottom surface of the groove 38 can be directed toward the color filters 36 rather than toward the light blocking film 35 due to the reverse lens effect, enabling suppression of degradation of image quality caused by the groove 38.

FIG. 17 depicts cross-sectional view illustrating a structure of a solid-state imaging apparatus according to another modified example of the second embodiment.

The solid-state imaging apparatus according to the modified example depicted in A of FIG. 17 includes a glass seal resin 64 and glass 65 provided on the cover film 62 in this order, in addition to the components depicted in A of FIG. 16. The glass 65 according to the present modified example is joined to the cover film 62 by the glass seal resin 64. The glass 65, for example, forms a part of a package of the solid-state imaging apparatus.

The solid-state imaging apparatus according to the modified example depicted in B of FIG. 17 includes the glass seal resin 64 and the glass 65 provided on the cover film 62 in this order, in addition to the components depicted in B of FIG. 16, as is the case with the modified example depicted in A of FIG. 17. However, the glass seal resin 64 according to the present modified example is also embedded in the grooves 38 and 63. The glass seal resin 64 is an example of a second film according to the present disclosure.

The glass seal resin 64 according to the present embodiment has a lower refractive index than the lens 37. For example, the refractive index of the glass seal resin 64 is lower than 1.5, and the refractive index of the lens 37 is higher than 1.5. According to the present modified example, the glass seal resin 64 having a lower refractive index than the lens 37 is provided in the groove 38, allowing light to be made less likely to leak from the lens 37 into the groove 38.

Further, the glass seal resin 64 according to the present modified example has a lower refractive index than the planarization film 61. For example, the refractive index of the glass seal resin 64 is lower than 1.3, but the refractive index of the planarization film 61 is higher than 1.3. According to the present modified example, the glass seal resin 64 having a lower refractive index than the planarization film 64 is provided in the groove 63, allowing light to be made less likely to leak from the planarization film 64 into the groove 63. Note that the glass seal resin 64 has a refractive index ranging, for example, from 1.15 to 1.3. Further, in a case where the planarization film 64 is fluorine-containing siloxane, the refractive index of the planarization film 64 can range, for example, from 1.3 to 1.45.

Note that further details of the solid-state imaging apparatus including the planarization film 61, the glass seal resin 64, the glass 65, and the like will be described later in a third embodiment.

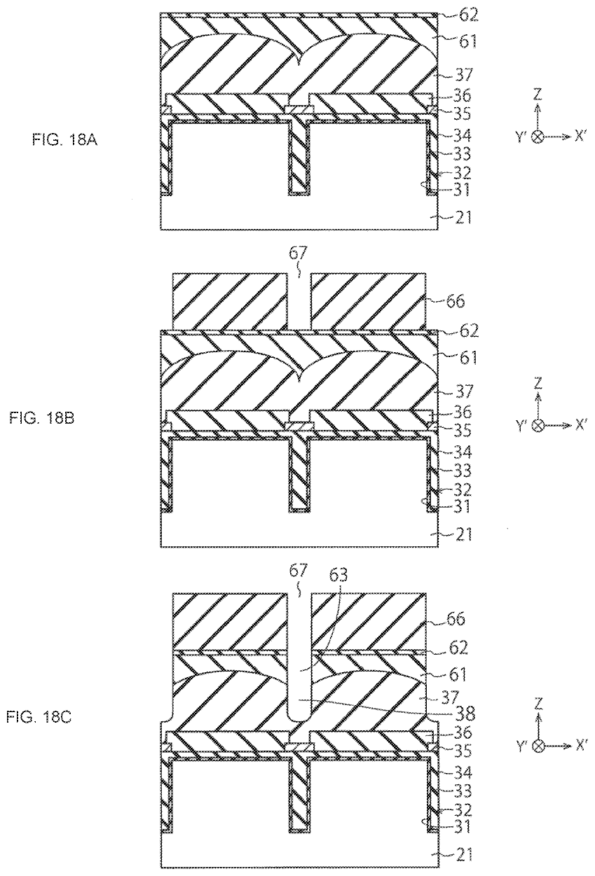

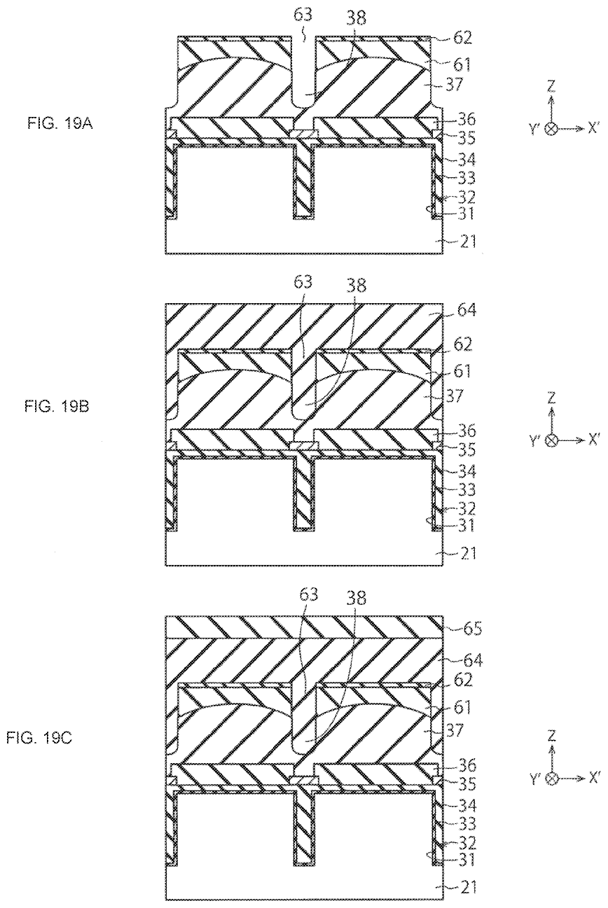

FIGS. 18 and 19 are cross-sectional views depicting a method for manufacturing a solid-state imaging apparatus according to the second embodiment.

First, after the steps depicted in A of FIG. 11 to A of FIG. 13 are executed, the planarization film 61 and the cover film 62 are formed on the lens 37 in this order (A of FIG. 18). Next, a resist film 66 is formed on the cover film 62, and a groove 67 is formed in the resist film 66 by lithography and etching (B of FIG. 18). The groove 67 is formed above the region in which the grooves 38 and 63 are to be formed.

Then, the cover film 62, the planarization film 61, and the material forming the lens 37 are processed by dry etching using the resist film 66 as a mask (C of FIG. 18). As a result, the groove 67 in the resist film 66 is transferred to the cover film 62, the planarization film 61, and the material forming the lens film 37. This forms the groove 63 penetrating the cover film 62 and the planarization film 61, and further forms the groove 38 between the lenses 37. The groove 38 is formed between two adjacent lenses 37 or between four adjacent lenses 37. Thus, the groove 38 that includes the first portion 38a and the second portion 38b described above is formed. Subsequently, the resist film 66 is removed (A of FIG. 19).

The groove 38 according to the present embodiment is formed such that the bottom surface of the groove 38 is shaped to protrude downward. Such a groove 38 can be formed by, for example, performing defocusing during exposure of the resist film 66 such that the front surface of the groove 67 in the resist film 66 is reversely tapered. Note that the groove 38 shaped to protrude downward may be formed using any other method.

Then, the glass seal resin 64 is formed all over the substrate 21 by a coating method (B of FIG. 19). As a result, the glass seal resin 64 is formed on the upper surface of the cover film 62 and in the grooves 38 and 63. Then, the glass 65 is joined to the cover film 62 by the glass seal resin 64 (C of FIG. 19). In such a manner, the solid-state imaging apparatus depicted in B of FIG. 17 is manufactured.

Note that, when the solid-state imaging apparatus depicted in A of FIG. 17 is manufactured, the steps depicted in A of FIG. 18, B of FIG. 19, and C of FIG. 19 are executed after the steps depicted in A of FIG. 11 to B of FIG. 13 are executed. Further, in a case where the anti-reflection film 51 or 52 is provided in the solid-state imaging apparatus according to the present embodiment, for example, the anti-reflection film 51 or 52 is formed on the lens 38 before the step in A of FIG. 18 is executed.

Note that the groove 38 according to the present embodiment includes a bottom surface shaped to protrude downward both in the first portion 38a and in the second portion 38b. However, the groove 38 according to the present embodiment is formed such that the lower end Pb of the second portion 38b is lower than the lower end Pa of the first portion 38a. Thus, the depth Db of the second portion 38b is greater than the depth Da of the first portion 38a (see A to C of FIG. 4). This is because when, in the step in C of FIG. 18, the first portion 38a and the second portion 38b of the groove 38 are simultaneously formed by etching, the second portion 38b is naturally formed deeper than the first portion 38a due to the characteristics of etching. Note that the depth Db of the second portion 38b may be greater than the depth Db of the first portion 38a for another reason or may be the same as the depth Da of the first portion 38b.

As described above, the lens 37 according to the present embodiment includes the groove 38 provided between the lenses 37, and the groove 38 includes the bottom surface shaped to protrude downward, as is the case with the first embodiment. Thus, according to the present embodiment, the bottom surface shaped to protrude downward can suppress degradation of image quality caused by the groove 38 between the lenses 37.

### Third Embodiment

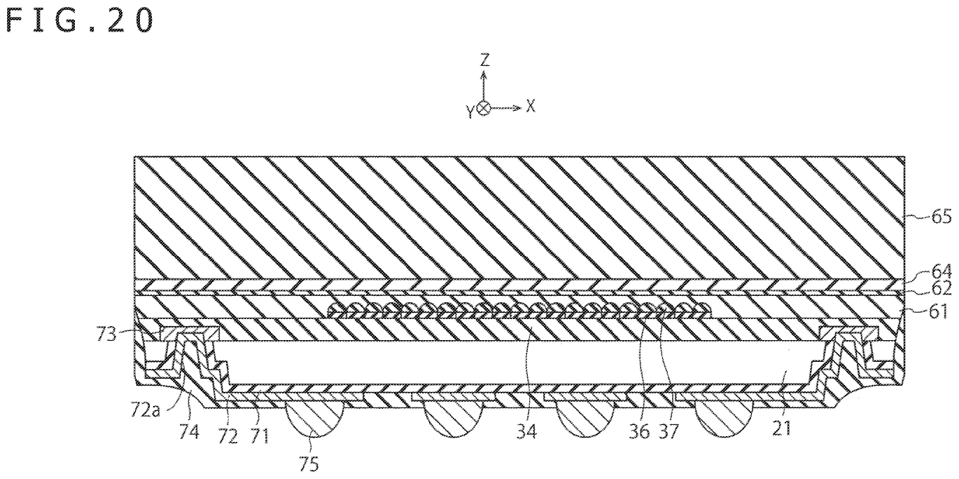

FIG. 20 is a cross-sectional view depicting a structure of a solid-state imaging apparatus according to a third embodiment.

The solid-state imaging apparatus according to the present embodiment includes an insulating film 71, a wiring layer 72, multiple metal pads 73, a solder mask 74, and multiple solder balls 75, in addition to components similar to those of the solid-state imaging apparatus depicted in A of FIG. 17. However, FIG. 20 depicts a larger region than A of FIG. 17, and hence, some of the components (for example, the groove 38) depicted in FIG. 17A are omitted.

FIG. 20 depicts, on the substrate 21 resulting from dicing and having a chip size, the planarization film 61 provided to cover the color film 36 and the lenses 37, the cover film 62, the glass seal resin 64, and the glass 65. The solid-state imaging apparatus according to the present embodiment is packaged by WLCSP (Wafer Level Chip Size/Scale Package). Accordingly, the size of the upper surface of the glass 65 is substantially the same as the size of the upper surface (back surface) of the substrate 21.

The insulating film 71 and the wiring layer 72 are provided on a lower surface of the substrate 21 in this order. On the other hand, a metal pad 73 is provided on the upper surface of the substrate 21. The wiring layer 72 includes multiple via wires 72a penetrating the substrate 21, and the via wires 72a are in contact with a lower surface of the metal pad 73. This enables various devices on the upper surface of the substrate 21 to be electrically connected to the wiring layer 72. The metal pad 73 is, for example, an aluminum pad.

The solder mask 74 is provided on a lower surface of the wiring layer 72. The solder balls 75 are provided on a lower surface of the wiring layer 72 exposed from the solder mask 74. This enables the solid-state imaging apparatus according to the present embodiment to be electrically connected to any other apparatus via the solder balls 75.

The planarization film 61 according to the present embodiment is a resin covering the color film 36 and the lenses 37. According to the present embodiment, the resin can be formed in the groove 38. This allows saving of the need to execute the step of forming a film in the groove 38 separately from the step of covering the color film 36 and the lenses 37 with resin.

Note that the solid-state imaging apparatus according to the present embodiment may include components similar to those of the solid-state imaging apparatus depicted in B of FIG. 17. In this case, the glass seal resin 64 is formed in the groove 38 (and the groove 63). This allows saving of the need to execute the step of forming a film in the groove 38 separately from the step of forming the glass seal resin 64.

Further, the solid-state imaging apparatus according to the present embodiment may include a spacer resin provided on an end surface of the substrate 21 in such a manner to surround the color film 36 and the lenses 37 like a ring instead of a resin used as the planarization film 61. In this case, the groove 38 is exposed to the air as in the case of the solid-state imaging apparatus according to the first embodiment. As described above, the structure of the present embodiment can be applied to the first embodiment as well as to the second embodiment.

As described above, the solid-state imaging apparatus according to the present embodiment is packaged by the WLCSP as illustrated in FIG. 20. According to the present embodiment, a reduction in package size, corresponding to an advantage of the WLCSP, is enjoyed, while the structure of the solid-state imaging apparatus according to the first embodiment and the second embodiment can be implemented.

While embodiments of the present disclosure have been described above, various changes may be made to the embodiments for implementation without departing from the spirits of the present disclosure. For example, two or more embodiments may be combined for implementation.

Note that the present disclosure can also take the configurations described below.

(1)

A solid-state imaging apparatus including:

multiple photoelectric conversion sections; and

multiple lenses provided above the multiple photoelectric conversion sections, in which

the multiple lenses each include a groove provided between the lenses, and

the groove includes a bottom surface shaped to protrude downward.

(2)

The solid-state imaging apparatus according to (1), in which

the groove includes a first portion sandwiched between two adjacent lenses and a second portion sandwiched between four adjacent lenses, and

a lower end of the second portion is located at a position lower than a lower end of the first portion.

(3)

The solid-state imaging apparatus according to (2), further including:

a light blocking film provided below the first portion and the second portion.

(4)

The solid-state imaging apparatus according to (1), in which

an upper end of the groove is an inflexion point of a curvature of a front surface of the lens.

(5)

The solid-state imaging apparatus according to (1), in which

a vertical cross section of the bottom surface of the groove is shaped like a semi-circle, a triangle, or a trapezoid.

(6)

The solid-state imaging apparatus according to (1), in which

a vertical end surface of the bottom surface of the groove is shaped symmetrically with respect to a center line of a vertical cross section of the groove.

(7)

The solid-state imaging apparatus according to (1), in which

a width of the groove at a certain height decreases consistently with the height.

(8)

The solid-state imaging apparatus according to (1), in which

a front surface of the groove includes an inflexion point of a curvature located at a position lower than an upper end of the groove but higher than a lower end of the groove.

(9)

The solid-state imaging apparatus according to (8), in which,

for a slope angle of the front surface of the groove, an angle between the upper end and the inflexion point is smaller than an angle between the inflexion point and the lower end.

(10)

The solid-state imaging apparatus according to (9), in which

the slope angle of the front surface of the groove is smaller than 30 degrees between the upper end and the inflexion point.

(11)

The solid-state imaging apparatus according to (9), in which

the slope angle of the front surface of the groove is smaller than 90 degrees between the inflexion point and the lower end.

(12)

The solid-state imaging apparatus according to (2), further including:

multiple color filters provided between the multiple photoelectric conversion sections and the multiple lenses, in which

a width of the second portion is equal to or larger than a distance between the color filters, and

a height of the lower end of the second portion is higher than a height of an upper surface of the color filter.

(13)

The solid-state imaging apparatus according to (1), further including:

an anti-reflection film provided on an upper surface of the lens.

(14)

The solid-state imaging apparatus according to (13), in which

the anti-reflection film is further provided on a front surface of the groove.

(15)

The solid-state imaging apparatus according to (1), further including:

a first film that is provided in the groove and has a lower refractive index than the lens.

(16)

The solid-state imaging apparatus according to (15), in which

the first film is further provided on an upper surface of the lens.

(17)

The solid-state imaging apparatus according to (1), further including:

a first film provided on an upper surface of the lens; and

a second film that is provided in the groove and has a lower refractive index than the lens.

(18)

The solid-state imaging apparatus according to (17), in which

the second film has a lower refractive index than the first film.

(19)

The solid-state imaging apparatus according to (17), in which

the second film includes a glass seal resin for providing glass above the first film.

(20)

The solid-state imaging apparatus according to (1), in which the

solid-state imaging apparatus is packaged by WLCSP (Wafer Level Chip Size/Scale Package).

(21)

A method for manufacturing a solid-state imaging apparatus, the method including:

forming multiple photoelectric conversion sections;

forming multiple lenses above the multiple photoelectric conversion sections; and

forming a groove between the lenses, the groove including a bottom surface shaped to protrude downward.

(22)

The method for manufacturing the solid-state imaging apparatus according to (21), in which

the groove includes a first portion sandwiched between two adjacent lenses and a second portion sandwiched between four adjacent lenses, and

a lower end of the second portion is formed at a position lower than a lower end of the first portion.

(23)

The method for manufacturing the solid-state imaging apparatus according to (21), further including:

forming an anti-reflection film on an upper surface of the lens and on a front surface of the groove after forming the groove between the lenses.

(24)

The method for manufacturing the solid-state imaging apparatus according to (21), further including:

forming an anti-reflection film on an upper surface of the lens before forming the groove between the lenses, in which

the groove is formed between the lenses such that a hole penetrates the anti-reflection film.

(25)

The method for manufacturing the solid-state imaging apparatus according to (21), further including:

forming, in the groove, a first film having a lower refractive index than the lens.

### REFERENCE SIGNS LIST

1: Pixel
2: Pixel array region
3: Control circuit
4: Vertical driving circuit
5: Column signal processing circuit
6: Horizontal driving circuit
7: Output circuit
8: Vertical signal line
9: Horizontal signal line
11: Support substrate
12, 13, 14: Wiring layer
15: Interlayer insulating film
16: Gate electrode
17: Gate insulating film
21: Substrate
22: Photoelectric conversion section
23: p-type semiconductor region
24: n-type semiconductor region
25: p-type semiconductor region
26: Pixel isolation layer
27: p well layer
28: Floating diffusion portion
31: Groove
32: Element isolation portion
33: Fixed charge film
34: Insulating film
35: Light blocking film
36: Color filter
37: On-chip lens
38: Groove
38a: First portion
38b: Second portion
41, 42, 43: Gate electrode
44, 45, 46, 47: Source drain region
51: Anti-reflection film
52: Anti-reflection film
53: Resist film
54: Groove
61: Planarization film
62: Cover film
63: Groove
64: Glass seal resin
65: Glass
66: Resist film
67: Groove
71: Insulating film
72: Wiring layer
72a: Via wire
73: Metal pad
74: Solder mask
75: Solder ball

1. A solid-state imaging apparatus comprising:
multiple photoelectric conversion sections; and
multiple lenses provided above the multiple photoelectric conversion sections, wherein
the multiple lenses each include a groove provided between the lenses, and
the groove includes a bottom surface shaped to protrude downward.

2. The solid-state imaging apparatus according to claim 1, wherein
the groove includes a first portion sandwiched between two adjacent lenses and a second portion sandwiched between four adjacent lenses, and
a lower end of the second portion is located at a position lower than a lower end of the first portion.

3. The solid-state imaging apparatus according to claim 2, further comprising:
a light blocking film provided below the first portion and the second portion.

4. The solid-state imaging apparatus according to claim 1, wherein
an upper end of the groove is an inflexion point of a curvature of a front surface of the lens.

5. The solid-state imaging apparatus according to claim 1, wherein
a vertical cross section of the bottom surface of the groove is shaped like a semi-circle, a triangle, or a trapezoid.

6. The solid-state imaging apparatus according to claim 1, wherein
a vertical end surface of the bottom surface of the groove is shaped symmetrically with respect to a center line of a vertical cross section of the groove.

7. The solid-state imaging apparatus according to claim 1, wherein
a width of the groove at a certain height decreases consistently with the height.

8. The solid-state imaging apparatus according to claim 1, wherein
a front surface of the groove includes an inflexion point of a curvature located at a position lower than an upper end of the groove but higher than a lower end of the groove.

9. The solid-state imaging apparatus according to claim 8, wherein,
for a slope angle of the front surface of the groove, an angle between the upper end and the inflexion point is smaller than an angle between the inflexion point and the lower end.

10. The solid-state imaging apparatus according to claim 9, wherein
the slope angle of the front surface of the groove is smaller than 30 degrees between the upper end and the inflexion point.

11. The solid-state imaging apparatus according to claim 9, wherein
the slope angle of the front surface of the groove is smaller than 90 degrees between the inflexion point and the lower end.

12. The solid-state imaging apparatus according to claim 2, further comprising:
multiple color filters provided between the multiple photoelectric conversion sections and the multiple lenses, wherein
a width of the second portion is equal to or larger than a distance between the color filters, and
a height of the lower end of the second portion is higher than a height of an upper surface of the color filter.

13. The solid-state imaging apparatus according to claim 1, further comprising:
an anti-reflection film provided on an upper surface of the lens.

14. The solid-state imaging apparatus according to claim 13, wherein
the anti-reflection film is further provided on a front surface of the groove.

15. The solid-state imaging apparatus according to claim 1, further comprising:
a first film that is provided in the groove and has a lower refractive index than the lens.

16. The solid-state imaging apparatus according to claim 15, wherein
the first film is further provided on an upper surface of the lens.

17. The solid-state imaging apparatus according to claim 1, further comprising:
a first film provided on an upper surface of the lens; and
a second film that is provided in the groove and has a lower refractive index than the lens.

18. The solid-state imaging apparatus according to claim 17, wherein
the second film has a lower refractive index than the first film.

19. The solid-state imaging apparatus according to claim 17, wherein
the second film includes a glass seal resin for providing glass above the first film.

20. The solid-state imaging apparatus according to claim 1, wherein
the solid-state imaging apparatus is packaged by WLCSP (Wafer Level Chip Size/Scale Package).

21. A method for manufacturing a solid-state imaging apparatus, the method comprising:
forming multiple photoelectric conversion sections,
forming multiple lenses above the multiple photoelectric conversion sections, and
forming a groove each between the lenses, the groove including a bottom surface shaped to protrude downward.

22. The method for manufacturing the solid-state imaging apparatus according to claim 21, wherein
the groove includes a first portion sandwiched between two adjacent lenses and a second portion sandwiched between four adjacent lenses, and
a lower end of the second portion is formed at a position lower than a lower end of the first portion.

23. The method for manufacturing the solid-state imaging apparatus according to claim 21, further comprising:
forming an anti-reflection film on an upper surface of the lens and on a front surface of the groove after forming the groove between the lenses.

24. The method for manufacturing the solid-state imaging apparatus according to claim 21, further comprising:
forming an anti-reflection film on an upper surface of the lens before forming the groove between the lenses, wherein
the groove is formed between the lenses such that a hole penetrates the anti-reflection film.

25. The method for manufacturing the solid-state imaging apparatus according to claim 21, further comprising:
forming, in the groove, a first film having a lower refractive index than the lens.
